(19) United States
(12) Patent Application Publication
(10) Pub. No.: US 2006/0055948 A1
(43) Pub. Date: Mar. 16, 2006

(54) Picture color tone controlling method and apparatus

(75) Inventors: Ikuo Ozaki, Hiroshima-ken (JP); Syuuichi Takemoto, Hiroshima-ken (JP); Norifumi Tasaka, Hiroshima-ken (JP)

Correspondence Address: LOWE HAUPTMAN GILMAN AND BERNER, LLP, 1700 DIAGONAL ROAD, SUITE 300 /310, ALEXANDRIA, VA, 22314, US

(73) Assignee: MITSUBISHI HEAVY INDUSTRIES, LTD, Tokyo (JP)

(21) Appl. No.: 11/221,776

(22) Filed: Sep. 9, 2005

(30) Foreign Application Priority Data
Sep. 10, 2004 (JP) 2004-263912

(51) Int. Cl. G03F 3/08

(52) U.S. Cl. 358/1.9; 358/518

(57) ABSTRACT

A picture color tone controlling method and apparatus for a printing press is disclosed by which a noticed pixel for control can be set appropriately and the accuracy in color tone control can be enhanced. For each of ink supplying unit widths, a region which has a high autocorrelation for each of the ink colors is selected in a sensor pixel unit of a densitometer, and a region obtained by removing an edge portion of the pertaining ink color having a width of a predetermined number of pixels from the selected region is set as a noticed pixel for each of the ink colors. Then, a target color mixture halftone density is set for each of the ink supplying unit widths, and an actual color mixture halftone density for each of the ink supplying unit widths of an actually printed sheet is measured using the densitometer. Further, the color mixture halftone density is converted into a halftone dot area ratio and further into a monochromatic halftone density. Then, a solid density deviation is determined, and the ink supplying amount is adjusted for each of the ink supplying unit widths in response to the solid density deviation.

The application claims the benefit of Japanese Application Serial No. 2004-263912, filed Sep. 10, 2004, which is incorporated herein by reference in its entirety.

### BACKGROUND OF THE INVENTION

1) Field of the Invention

This invention relates to a picture color tone controlling method and apparatus for a printing press, and more particularly to a picture color tone controlling method and apparatus for controlling the color tone using an IRGB densitometer.

2) Description of the Related Art

Various techniques have been proposed as a technique for color tone control of a picture of a printing press.

For example, in techniques disclosed in Japanese Patent Laid-Open No. 2001-18364 (hereinafter referred to as Patent Document 1) and Japanese Patent Laid-Open No. 2001-47005 (hereinafter referred to as Patent Document 2), color tone control is performed in such a procedure as described below.

First, a spectral reflectance of a picture printed reflectance of each key zone is converted into a color coordinate value (L*a*b*) proposed by the International Commission on Illumination. If the ink supplying amount for each color is adjusted and test printing is performed and then a printing sheet (hereinafter referred to as OK sheet) having a desired color tone is obtained, then the color coordinate value for each key zone of the OK sheet is set as a target color coordinate value. Then, actual printing is started, and the difference (color difference) between the color coordinate values of the OK sheet and a printing sheet (printing sheet obtained by actual printing is hereinafter referred to as actual printing sheet) is calculated for each of the key zones. Thereafter, an increasing and decreasing amount for the opening of the ink key of each printing unit with respect to the color difference is calculated, and the opening of each ink key of each printing unit is adjusted by online control so that the color difference may be reduced to zero.

However, according to the techniques disclosed in Patent Documents 1 and 2, a spectrometer is used as a measurement section. The spectrometer requires a high cost. Further, where an object of measurement (in this instance, a printing sheet) moves at a very high speed as in the case of a rotary press for newspapers, the spectrometer cannot follow up the measurement object because of the processing capacity thereof. Further, in the method described above, since the color tone control is started after an OK sheet is printed, a great amount of paper loss appears after the printing process is started until the OK sheet is printed. Further, in the method described above, a picture in the key zone of each ink key is averaged over the entire key zone and the color tone control is performed based on the spectral reflectance after the averaging. Therefore, where the image line ratio of the picture in a key zone is low, a measurement error of the spectrometer increases and the control is likely to be rendered instable. Further, particularly severe color tone management is sometimes requested regarding a specific noticed point in a picture depending upon an order from a customer. Where the color tone control is to be performed for a specific noticed point in such a manner as just described, data such as CIP3 data [PPF (Print Production Format) data conforming to the standard of CIP3 (Cooperation for Integration of Prepress, Press, Postpress)] must be received as image data to be used as a reference from an upstream plate making step.

Japanese Patent Laid-Open No. 2004-106523 (hereinafter referred to as Patent Document 3) discloses a technique wherein, in order to solve such subjects as described above, color tone control is performed in accordance with the following procedure.

First, a target color mixture halftone density for each ink supplying unit width when a printing picture is divided by the ink supplying unit width of an ink supplying apparatus is set. It is to be noted that, where the ink supplying apparatus is an ink key apparatus, the ink supplying unit width of the ink supplying apparatus is the key width (key zone) of each ink key, but where the ink supplying apparatus is a digital pump apparatus, the ink supplying unit width is the pump width of each digital pump. It is to be noted that a setting method for the target color mixture halftone density is hereinafter described.

If printing is started and an actual printing sheet is obtained, then an actual color mixture halftone density for each ink supplying unit width of the actual printing sheet is measured using an IRGB densitometer. Then, an actual halftone dot area ratio for each ink color corresponding to the actual color mixture halftone density is calculated based on a corresponding relationship set in advance between halftone dot area ratios and color mixture halftone densities for the individual ink colors. As a method for calculating an actual halftone dot area ratio from an actual color mixture halftone density, a database wherein a relationship between halftone dot area ratios and color mixture halftone densities for individual ink colors is stored, for example, a database wherein data obtained by actual measurement, by means of an IRGB densitometer, of a printed matter printed in accordance with the JapanColor standards for Newspaper Printing established by the ISO/TC130 National Commission are stored, may be used. More simply, the database can be utilized also to utilize an approximate value calculated using the known Neugebauer expression. Further, a target halftone dot area ratio for each ink color corresponding to the target color mixture halftone density is calculated based on the corresponding relationship described above between halftone dot area ratios and color mixture halftone densities. Different from the actual halftone dot area ratio, the target halftone dot area ratio need not be calculated every time, but it is sufficient to calculate the target halftone dot area ratio once unless the target color mixture halftone density varies. For example, the target halftone dot area ratio may be calculated at a point of time when the target color mixture halftone density is set.

Then, an actual monochromatic halftone density corresponding to the actual halftone dot area ratio is calculated based on a corresponding relationship set in advance between halftone dot area ratios and monochromatic halftone densities. As a method of calculating an actual monochromatic halftone density from an actual halftone dot area ratio, a map or a table which represents a relationship between monochromatic halftone densities and halftone dot area ratios may be prepared such that the actual halftone dot area ratio is applied to the map or the table. More simply, the relationship described above may be approximated using the known Yule-Nielsen expression to calculate the actual monochromatic halftone density. Meanwhile, a target monochromatic halftone density corresponding to the target halftone dot area ratio is calculated based on the corresponding relationship described above between halftone dot area ratios and monochromatic halftone densities. Different from the actual monochromatic halftone density, the target monochromatic halftone density need not be calculated every time, and it is sufficient to calculate the target monochromatic halftone density once unless the target halftone dot area ratio varies. For example, the target monochromatic halftone density may be calculated at a point of time when the target halftone dot area ratio is set.

Then, a solid density deviation corresponding to a deviation between the target monochromatic halftone density and the actual monochromatic halftone density under the target halftone dot area ratio is calculated based on a corresponding relationship set in advance among halftone dot area ratios, monochromatic halftone densities and solid densities. As a method of calculating the solid density difference, a map or a table which represents the corresponding relationship described above is prepared, and then the target halftone dot area ratio, target monochromatic halftone density and actual monochromatic halftone density are applied to the map or table. More simply, the relationship described above may be approximated using the known Yule-Nielsen expression to calculate the solid density deviation. Then, the ink supplying amount is adjusted for each of the ink supplying unit widths based on the calculated solid density deviation and the ink supplying amount for each color is controlled for each of the ink supplying unit widths. The adjustment amount of the ink supplying amount based on the solid density deviation can be determined simply using the known API (Auto Preset Inking) function.

According to such a picture color tone controlling method as described above, since color tone control can be performed using not a spectrometer but an IRGB densitometer, the cost required for the measuring system can be reduced, and besides the picture color tone controlling method can be applied sufficiently also to a high speed printing press such as a rotary press for newspapers.

Meanwhile, as a technique for setting a target color mixture halftone density where kcmy halftone dot area ratio data of a printing object picture (for example, image data for plate making or the like) can be acquired from the outside (for example, a printing requesting source or the like), the following technique has been proposed.

First, the acquired image data (kcmy halftone dot area ratio data) are used to set a noticed pixel (a noticed pixel may be a single pixel or a plurality of contiguous pixels in a mass) corresponding to each of ink colors for each ink supplying unit width from among pixels which form the printing object picture. Then, the halftone dot area ratio of the noticed pixel is converted into a color mixture halftone density based on a corresponding relationship set in advance between halftone dot area ratios and color mixture halftone densities. Then, the color mixture halftone density of the noticed pixel is set as a target color mixture halftone density, and the actual color mixture halftone density of the set noticed pixel is measured.

According to the proposed technique, since color development can be estimated in a unit of a pixel by utilizing the database of JapanColor or the like, color tone control can be performed for a particular noticed point (noticed pixel) of the picture at a point of time immediately after printing is started without waiting that an OK sheet is printed. It is to be noted that the kcmy halftone dot area ratio data may be bitmap data of the printing object picture (for example, data for 1 bit-Tiff plating making). Or, low resolution data corresponding to CIP3 data obtained by conversion of such bitmap data may be used alternatively.

It is to be noted that, as a setting method of a noticed point (noticed picture), a method is available wherein an image of a printing picture is displayed on a display apparatus such as a touch panel using bitmap data such that an operator may designate a noticed point arbitrarily. Also a method has been proposed wherein a pixel having a maximum density sensitivity, or a pixel having a maximum autocorrelation to the halftone dot area ratio, is automatically extracted for each ink color through arithmetic operation and is set as a noticed pixel. In a particular setting method of a noticed pixel, an autocorrelation sensitivity H is introduced such that a pixel having a maximum autocorrelation sensitivity H is determined as a pixel having a maximum autocorrelation and is set as a noticed pixel. For example, the autocorrelation sensitivity Hc to cyan can be represented, using pixel area ratio data (c, m, y, k), as
“Hc=c²/(c+m+y+k)”
and a pixel having a maximum value of the autocorrelation sensitivity Hc is set as a noticed point of cyan.

If a pixel having a maximum autocorrelation with regard to a halftone dot area ratio is extracted through arithmetic operation and set as a noticed pixel for each ink color and a target monochromatic halftone density and an actual monochromatic halftone density are calculated with regard to the noticed pixel and then the ink supplying amount is feedback controlled so that the actual monochromatic halftone density may approach the target monochromatic halftone density in such a manner as described above, then stabilized color tone control can be achieved.

Incidentally, according to the technique described above, when it is tried to automatically set a noticed pixel, a pixel (one pixel or a plurality of contiguous pixels in a mass) having a maximum autocorrelation is set as a noticed pixel, while a basic unit for pixels to be printed is a pixel unit of plate making data, according to an IRGB densitometer which is a sensor for measuring the actual color mixture halftone density, it becomes more difficult to secure the resolution as the printing speed increases, and the resolution of the densitometer drops significantly when compared with the resolution of the plate making data.

Therefore, it is necessary to set a noticed pixel using a minimum unit of the resolution of the densitometer as a basic unit (this is hereinafter referred to as sensor pixel unit or one block). In this instance, a set of a large number of pixels of plate making data corresponds to one pixel (one block) of the sensor pixel unit. From such a point of view as just described, it is a possible idea to set blocks in a 50 obtained from plate making data as shown, for example, with reference characters C, M, Y and K in FIG. 12 (actual blocks are not so large as those shown in FIG. 12) such that a noticed pixel is set in a unit of a block.

On the other hand, according to the technique of Patent Document 3, while a pixel having a maximum autocorrelation sensitivity H is determined as a pixel having a maximum autocorrelation and set as a noticed pixel, the autocorrelation sensitivity H includes two conditions that the autocorrelation is high and that the standard deviation is small. Therefore, when a noticed pixel is set in a unit of a block, only ink of a certain color may sometimes be printed only by a small amount in a block while most part of the block is blank, and such a block as just described is sometimes determined as a block which has a maximum autocorrelation sensitivity to the pertaining ink color.

If a block having a maximum autocorrelation sensitivity selected in such a manner as described above is set to a noticed pixel, then the density of the pertaining ink color which is printed only a little in the block is detected to perform color tone control. This deteriorates the density detection sensitivity and hence deteriorates the accuracy in color tone control.

Further, if some displacement appears between a target image position and a current image position when the printing speed rises high or upon pastering (automatic splicing), then the accuracy in color tone control sometimes drops significantly.

### SUMMARY OF THE INVENTION

It is an object of the present invention to provide a picture color tone controlling method and apparatus wherein a noticed place (noticed pixel) for control can be set arbitrarily to enhance the accuracy in color tone control.

In order to attain the object described above, according to a picture color tone controlling method for a printing press of the present invention, a noticed pixel which is a reference region upon controlling is set corresponding to each of ink colors. Here, for each of ink supplying unit widths of an ink supplying apparatus when a printing picture is divided with the ink supplying unit width, a region (pixel group) which has a high autocorrelation for each of the ink colors is selected in a sensor pixel unit of an IRGB densitometer from kcmy halftone dot area ratio data obtained based on plate making picture information, and a region obtained by removing an edge portion of the pertaining ink color having a width of a predetermined number of pixels from the selected region is set as a noticed pixel for each of the ink colors (noticed pixel setting step).

After a noticed pixel corresponding to each of the ink colors is set in this manner, a target color mixture halftone density regarding the noticed pixel for each of the ink colors is set for each of the ink supplying unit widths. The ink supplying unit width of the ink supplying apparatus is the key width (key zone) of each ink key if the ink supplying apparatus is an ink key apparatus, but is the pump width of each digital pump if the ink supplying apparatus is a digital pump apparatus.

When printing is started and an actual printed sheet is obtained, an actual color mixture halftone density for each of the ink supplying unit widths of the actually printed sheet is measured using the IRGB densitometer. Then, an actual halftone dot area ratio with regard to the noticed pixel of each of the ink colors corresponding to the actual color mixture halftone density is determined based on a corresponding relationship between halftone dot area ratios and color mixture halftone densities set in advance for each of the ink colors. As a method for determining an actual halftone dot area ratio from an actual color mixture halftone density, a database wherein the relationship between the halftone dot area ratios and the color mixture halftone densities for individual ink colors is stored, for example, a database wherein data obtained by actual measurement, by means of an IRGB densitometer, of a printed matter printed in accordance with the JapanColor standards for Newspaper Printing established by the ISO/TC130 National Commission are stored, may be used. More simply, the database can be utilized also to utilize an approximate value calculated using the known Neugebauer expression. Further, a target halftone dot area ratio for each ink color corresponding to the target color mixture halftone density is calculated based on the corresponding relationship described above between halftone dot area ratios and color mixture halftone densities. Different from the actual halftone dot area ratio, the target halftone dot area ratio need not be calculated every time, but it is sufficient to calculate the target halftone dot area ratio once unless the target color mixture halftone density varies. For example, the target halftone dot area ratio may be determined at a point of time when the target color mixture halftone density is set.

Then, an actual monochromatic halftone density corresponding to the actual halftone dot area ratio is determined based on a corresponding relationship between halftone dot area ratios and monochromatic halftone densities. As a method of determining the actual monochromatic halftone density from the actual halftone dot area ratio, a map or a table which represents a relationship between monochromatic halftone densities and halftone dot area ratios may be prepared such that the actual halftone dot area ratio is applied to the map or the table. More simply, the relationship described above may be approximated using the known Yule-Nielsen expression to determine the actual monochromatic halftone density. Meanwhile, the target monochromatic halftone density corresponding to the target halftone dot area ratio may be calculated based on the corresponding relationship described above between halftone dot area ratios and monochromatic halftone densities. Different from the actual monochromatic halftone density, the target monochromatic halftone density need not be calculated every time, and it is sufficient to calculate the target monochromatic halftone density once unless the target halftone dot area ratio varies. For example, the target monochromatic halftone density maybe determined at a point of time when the target halftone dot area ratio is set.

Then, based on a corresponding relationship set in advance among the halftone dot area ratios, the monochromatic halftone densities and solid densities, a solid density deviation corresponding to a deviation between the target monochromatic halftone density and the actual monochromatic halftone density under the target halftone dot area ratio is determined. As a method of calculating the solid density difference, a map or a table which represents the corresponding relationship described above is prepared, and then the target halftone dot area ratio, target monochromatic halftone density and actual monochromatic halftone density are applied to the map or table. More simply, the relationship described above may be approximated using the known Yule-Nielsen expression to determine the solid density deviation. Then, the ink supplying amount is adjusted for each of the ink supplying unit widths based on the calculated solid density deviation and the ink supplying amount for each color is controlled for each of the ink supplying unit widths. The adjustment amount of the ink supplying amount based on the solid density deviation can be determined simply using the known API (Auto Preset Inking) function which is described in detail in the description of preferred embodiments of the present invention hereinafter given.

In this manner, according to the picture color tone controlling method for a printing press of the present invention, a noticed pixel which is a reference region upon controlling is set corresponding to each of ink colors. Thereupon, for each of ink supplying unit widths of the ink supplying apparatus when a printing picture is divided with the ink supplying unit width, a region which has a high autocorrelation for each of the ink colors is selected in a sensor pixel unit of the IRGB densitometer from kcmy halftone dot area ratio data obtained based on plate making picture information. Further, a region obtained by removing an edge portion (that is, a portion which is contiguous to a blank portion) of the pertaining ink color having a width of a predetermined number of pixels from the selected region is set as a noticed pixel. Therefore, it is possible to prevent a blank region from being included in the noticed pixel, and consequently, a drop of the density detection sensitivity can be prevented to assure a high degree of accuracy in color tone control. Therefore, even if some displacement appears between the target image position and the current image position when the printing speed rises high or upon pastering (automatic splicing), a significant drop of the accuracy in color tone control can be prevented.

It is to be noted that the noticed pixel setting step may be configured such that, when a noticed pixel is set in such a manner as described above, a region which has a high autocorrelation for each of the ink colors is selected, and, if the noticed pixel remains present in the selected region even if an edge portion with regard to the pertaining ink color having a width of a predetermined number of pixels is removed from the selected region, then the remaining region of the selected region from which the edge portion is removed is set as the noticed pixel of the pertaining ink color, but if the noticed pixel does not remain when the edge portion having the width of the predetermined number of pixels is removed from the selected region, then the region which has the high autocorrelation is set as the noticed pixel of the pertaining ink color without removing the edge portion from the selected region.

In this instance, while a drop of the density detection sensitivity is prevented by removing an edge portion having the predetermined number of pixels from within the selected region to prevent a blank portion from being included in the noticed pixel, for such a small selected region (region having a high autocorrelation) that the noticed pixel disappears if an edge portion having the width of the predetermined number of pixels is removed from the selected region, the noticed pixel itself is assured even if the density detection sensitivity drops, and consequently, a high degree of accuracy in color tone control can be assured. In short, since the disappearance of the noticed pixel itself deteriorates the accuracy in color tone control more than the drop of the density detection sensitivity, this is prevented so that a high degree of accuracy in color tone control can be assured.

Preferably, at the noticed pixel setting step, when the edge portion with regard to the pertaining ink color is removed from within the selected region, the edge portion is removed by only one pixel in the sensor pixel unit. This makes it possible to prevent a blank portion from being included in the noticed pixel while assuring the noticed pixel of a size as large as possible. Consequently, a high degree of accuracy in color tone control can be assure.

Preferably, the region which has a high autocorrelation at the noticed pixel setting step is a group of all those pixels which have an autocorrelation higher than a condition set in advance for each of the ink colors. This makes it possible to assure the noticed pixel of a size as large as possible while preventing a blank portion from being included in the noticed pixel. Consequently, a high degree of accuracy in color tone control can be assure. Preferably, the noticed pixel setting step is configured as a noticed pixel automatic setting step at which a computer is used to automatically extract the group of pixels. This makes it possible to set the noticed pixel without relying upon the operator.

More preferably, the picture color tone controlling method for a printing press further comprises a noticed pixel manual setting step at which the noticed pixel is set manually by an operator separately from the noticed pixel automatic setting step, and the target color mixture halftone density setting step, the actual color mixture halftone density measuring step, the target halftone dot area ratio calculation step, the actual halftone dot area ratio calculation step, the target monochromatic halftone density calculation step, the actual monochromatic halftone density calculation step and the solid density deviation calculation step are carried out for both of a first noticed pixel which is the noticed pixel set by the noticed pixel automatic setting step and a second noticed pixel which is the noticed pixel set by the noticed pixel manual setting step to obtain two solid density deviations, and then at the ink supplying amount adjusting step, the ink supplying amount is adjusted for each of the ink supplying unit widths based on the two solid density deviations.

In the picture color tone controlling method for a printing press, the noticed pixel can be set from both sides of automatic setting in accordance with an objective reference by a computer and manual setting in accordance with the subject based on the experience of the operator, and a noticed pixel which includes an intention of the operator and is objectively effective is set. Consequently, the liking of the operator can be reflected on the color tone control.

In this instance, at the ink supplying amount adjusting step, preferably the solid density deviation obtained with regard to the first noticed pixel and the solid density deviation obtained with regard to the second noticed pixel are weighted averaged in accordance with a weighting condition set in advance, and the ink supplying amount is adjusted for each of the ink supplying unit widths based on the solid density deviation obtained by the weighted averaging.

In the picture color tone controlling method for a printing press, the degree of the reflection of the intention of the operator can be adjusted. For example, if the operator is a skilled person, then if the operator sets the weighting condition so that importance is attached to the solid density deviation obtained with regard to the second noticed pixel set by the operator itself to adjust the ink supplying amount, then color tone control on which the judgment of the operator itself is reflected much can be carried out. On the other hand, if the operator has comparatively poor experience, then if the operator sets the weighting condition so that importance is attached to the solid density deviation obtained with regard to the first noticed pixel which is automatically set by the computer to adjust the ink supplying amount, then color tone control can be carried out without suffering from a drop of the accuracy while the liking of the operator itself is reflected suitably on the color tone control.

It is to be noted that the picture color tone controlling method for a printing press described above can be carried out by a picture color tone controlling apparatus having the following configuration.

In particular, the picture color tone controlling apparatus for a printing press of the present invention comprises, as components thereof, an ink supplying apparatus for supplying ink for each of divisional regions divided in a printing widthwise direction, and an IRGB densitometer (preferably, a line sensor type IRGB densitometer) disposed on a feeding line of an actually printed sheet obtained by printing, as well as noticed pixel setter, target color mixture halftone density setter, color mixture halftone density measurer, target halftone dot area ratio arithmetic obtainer, actual halftone dot area ratio arithmetic obtainer, target monochromatic halftone density arithmetic obtainer, actual monochromatic halftone density arithmetic obtainer, solid density difference arithmetic obtainer, and ink supplying amount adjuster.

Of the components mentioned, the noticed pixel setter, target color mixture halftone density setter, color mixture halftone density measurer, target halftone dot area ratio arithmetic obtainer, actual halftone dot area ratio arithmetic obtainer, target monochromatic halftone density arithmetic obtainer, actual monochromatic halftone density arithmetic obtainer, solid density difference arithmetic obtainer, and ink supplying amount adjuster can be implemented as programmed functions of a computer.

The functions are described. First, the noticed pixel setter has a function of setting a noticed pixel which is a reference region upon controlling corresponding to each of ink colors, particularly a function of selecting, for each of ink supplying unit widths of the ink supplying apparatus when a printing picture is divided with the ink supplying unit width, from kcmy halftone dot area ratio data obtained based on plate making picture information, a region which has a high autocorrelation for each of the ink colors in a sensor pixel unit of an IRGB densitometer and setting, for each of the ink colors, a region obtained by removing an edge portion with regard to the pertaining ink color having a width of a predetermined number of pixels from the selected region as a noticed pixel for the ink color.

The target color mixture halftone density setter has a function of setting a target color mixture halftone density for each of ink supplying unit widths of the ink supplying apparatus when a printing picture is divided with the ink supplying unit width. The color mixture halftone density measurer has a function of making use of the IRGB densitometer to measure an actual color mixture halftone density for each of the ink supplying unit widths of an actually printed sheet. The target halftone dot area ratio arithmetic obtainer has a function of arithmetically operating a target halftone dot area ratio of each ink color corresponding to the target color mixture halftone density based on a corresponding relationship (for example, the Neugebauer expression) set in advance between halftone dot area ratios and color mixture halftone densities. The actual halftone dot area ratio arithmetic obtainer has a function of arithmetically operating an actual halftone dot area ratio of each ink color corresponding to the actual color mixture halftone density based on the same corresponding relationship. The target monochromatic halftone density arithmetic obtainer has a function of determining a target monochromatic halftone density corresponding to the target halftone dot area ratio based on a corresponding relationship (for example, the Yule-Nielsen expression) set in advance between the halftone dot area ratios and monochromatic halftone densities. The actual monochromatic halftone density arithmetic obtainer has a function of determining an actual monochromatic halftone density corresponding to the actual halftone dot area ratio based on the said corresponding relationship. The solid density difference arithmetic obtainer has a function of determining, based on a corresponding relationship (for example, the Yule-Nielsen expression) set in advance among the halftone dot area ratios, the monochromatic halftone densities and solid densities, a solid density deviation corresponding to a deviation between the target monochromatic halftone density and the actual monochromatic halftone density under the target halftone dot area ratio. Further, the ink supplying amount adjuster has a function of adjusting an ink supplying amount of the ink supplying apparatus for each of the ink supplying unit widths based on the solid density deviation, for example, using an API function. Preferably, the picture color tone controlling apparatus for a printing press further comprises a conversion table which defines a corresponding relationship among the halftone dot area ratios, the color mixture halftone densities and color coordinate values in the IRGB densitometer, the target halftone dot area ratio arithmetic obtainer and the actual halftone dot area ratio arithmetic obtainer using the conversion table to determine the target halftone dot area ratio or the actual halftone dot area ratio.

The noticed pixel setter may be configured such that, when a region which has a high autocorrelation is to be selected for each of the ink colors, if the noticed pixel remains present in the selected region even if an edge portion with regard to the pertaining ink color having a width of a predetermined number of pixels is removed from the selected region, then the remaining region of the selected region from which the edge portion is removed is set as the noticed pixel of the pertaining ink color, but if the noticed pixel does not remain when the edge portion having the width of the predetermined number of pixels is removed from the selected region, then the region which has the high autocorrelation is set as the noticed pixel of the pertaining ink color without removing the edge portion from the selected region.

Preferably, the noticed pixel setter removes, when the edge portion with regard to the pertaining ink color is removed in a unit of a sensor pixel from within the selected region, the edge portion by only one pixel in the sensor pixel unit.

Here, preferably the region which has a high autocorrelation at the noticed pixel setter is a group of all those pixels which have an autocorrelation higher than a condition set in advance for each of the ink colors, and preferably the noticed pixel setter is configured as noticed pixel automatic setter which uses a computer to automatically extract the group of pixels.

Further preferably, the picture color tone controlling apparatus for a printing press further comprises noticed pixel manual setter for being operable by an operator to manually set the noticed pixel separately from the noticed pixel automatic setter, and the target color mixture halftone density setter, the actual color mixture halftone density measurer, the target halftone dot area ratio calculator, the actual halftone dot area ratio calculator, the target monochromatic halftone density calculator, the actual monochromatic halftone density calculator and the solid density deviation calculator carry out the respective processes for both of a first noticed pixel which is the noticed pixel set by the noticed pixel automatic setter and a second noticed pixel which is the noticed pixel set by the noticed pixel manual setter to obtain two solid density deviations, and the ink supplying amount adjuster adjusts the ink supplying amount for each of the ink supplying unit widths based on the two solid density deviations. As one of manual setting methods of a noticed point in this instance, a method is available wherein an image of a printing picture is displayed on a display apparatus such as a touch panel such that the operator can arbitrarily designate a noticed point on the display apparatus.

In this instance, preferably the picture color tone controlling apparatus for a printing press further comprises weighting setter for setting a weighting condition for the solid density deviation obtained with regard to the first noticed pixel and the solid density deviation obtained with regard to the second noticed pixel, and the ink supplying amount adjuster weighted averages the solid density deviation obtained with regard to the first noticed pixel and the solid density deviation obtained with regard to the second noticed pixel in accordance with the weighting condition set by the weighting setter and adjusts the ink supplying amount for each of the ink supplying unit widths based on the solid density deviation obtained by the weighted averaging.

Further, the target color mixture halftone density is set in the following manner. First, kcmy halftone dot area ratio data (for example, image data for plating making or the like) of a printing object picture which can be acquired from plate making data are used to set a noticed image corresponding to each ink color for each ink supplying unit width from among pixels which form the printing object picture. Then, the halftone dot area ratio of the noticed pixel is converted into a color mixture halftone density based on a corresponding relationship set in advance between halftone dot area ratios and color mixture halftone densities. Then, the color mixture halftone density of the noticed pixel is set as a target color mixture halftone density, and the actual color mixture halftone density of the set noticed pixel is measured. According to the setting method, since color development can be estimated in a unit of a pixel by utilizing the database of JapanColor or the like, color tone control can be performed for a particular noticed point of the picture at a point of time immediately after printing is started without waiting that an OK sheet is printed. It is to be noted that the kcmy halftone dot area ratio data may be bitmap data of the printing object picture (for example, data for 1 bit-Tiff plating making). Or, CIP3 data corresponding to 50.8 dpi or equivalent resolution conversion data (data obtained by conversion of 1 bit-Tiff plate making data of 1,200 dpi or 2,400 dpi into 8 bit-Tiff data of 50 dpi) may be used alternatively. Or else, low resolution data corresponding to CIP3 data obtained by conversion of bitmap data may be used instead.

Furthermore, where also an ICC (International Color Consortium) profile can be acquired in addition to kcmy halftone dot area ratio data of a printing object picture, noticed pixels corresponding to the individual ink colors are set for each of the ink supplying unit widths from among the pixels which form the printing object picture, and the halftone dot area ratios of the noticed pixels are converted into color mixture halftone densities using the ICC profile and a device profile of the IRGB densitometer. Then, the color mixture halftone densities of the noticed pixels are set as the target color mixture halftone densities, and the actual color mixture halftone densities of the set noticed pixels are measured. By controlling the color tone based on the ICC profile obtained from a printing requesting source or the like in this manner, a printed matter of a color tone desired by the printing requesting source or the like can be obtained readily.

It is to be noted that, in order to convert the halftone dot area ratio of the noticed pixel into the color mixture halftone density, the halftone dot area ratio is converted once into a color coordinate value using the ICC profile, and then the color coordinate value is converted into the color mixture halftone density. However, since the color mixture halftone density is four-dimensional information while the color coordinate value is three-dimensional information, the color mixture halftone density corresponding to the color coordinate value is not determined uniquely. Therefore, the present invention provides a method of selecting, in such development from three-dimensional information to four-dimensional information, the most agreeable piece of the four-dimensional information from among a large number of pieces of the four-dimensional information which may make a candidate. First, it is presupposed that the device profile of the IRGB densitometer is a conversion table which defines a corresponding relationship among halftone dot area ratios, color mixture halftone densities and color coordinate values in the IRGB densitometer. Then, the ICC profile is used to convert the halftone dot area ratio of a noticed pixel into a color coordinate value and determine a plurality of color mixture halftone density candidates corresponding to the color coordinate value from within the conversion table and then convert the halftone dot area ratio of the noticed element into a color coordinate value using the conversion table. Then, the color difference between the two color coordinate values obtained by the conversion through the ICC profile and the conversion through the conversion table is determined, and the variation amount of the halftone dot area ratio corresponding to the color difference is arithmetically operated using mathematical means such as minimum approximation. Then, the determined variation amount is added to the halftone dot area ratio of the noticed pixel, and the resulting value is determined as a virtual halftone dot area ratio. Then, one of the color mixture density candidates which most corresponds to the virtual half tone dot area ratio is selected by referring to the conversion table, and the selected color mixture halftone density candidate is set as a color mixture halftone density of the noticed pixel. In this manner, according to the present method, a color mixture halftone density corresponding to a color coordinate value can be decided uniquely by utilizing the halftone dot area ratio corresponding to the color coordinate value.

More preferably, an actual color coordinate value corresponding to the actual color mixture halftone density of the noticed pixel measured by the IRGB densitometer and a target color coordinate value corresponding to the target color mixture halftone density are determined based on a corresponding relationship set in advance between color mixture halftone densities and color coordinate values. Then, a color difference between the actual color coordinate value and the target color coordinate value is determined, and the actual color coordinate value and/or the color difference are displayed on a display apparatus. According to the method, it can be recognized intuitively by the operator by which level colors coincide with each other.

According to the picture color tone controlling method and apparatus of the present invention having such a configuration as described above, since color tone control can be performed using not a spectrometer but an IRGB densitometer, the cost required for the measuring system for measuring a positional displacement can be reduced, and besides the picture color tone controlling method and apparatus can be applied sufficiently also to a high speed printing press such as a rotary press for newspapers.

Besides, when a noticed pixel which is to be used as a reference region upon controlling corresponding to each ink color is to be set first, a region which has a high autocorrelation with regard to each ink color is selected, and a region obtained by removing an edge portion (that is, a portion contiguous to a blank region) of the pertaining ink color having a width of a predetermined number of pixel from the selected region is set as a noticed pixel. Therefore, it is possible to prevent a blank region from being included in the noticed pixel, and consequently, a drop of the density detection sensitivity can be prevented and the accuracy in color tone control can be assured. Therefore, even if some displacement appears between a target image position and a current image position when the printing speed rises high or upon pastering (automatic splicing), a significant drop of the accuracy in color tone control can be prevented.

Further, if the picture color tone controlling method and apparatus is configured such that, when a noticed pixel is set in such a manner as described above, a region which has a high autocorrelation for each of the ink colors is selected, and, if the noticed pixel remains present in the selected region even if an edge portion with regard to the pertaining ink color having a width of a predetermined number of pixels is removed from the selected region, then the remaining region of the selected region from which the edge portion is removed is set as the noticed pixel of the pertaining ink color, but if the noticed pixel does not remain when the edge portion having the width of the predetermined number of pixels is removed from the selected region, then the region which has the high autocorrelation is set as the noticed pixel of the pertaining ink color without removing the edge portion from the selected region, then while a drop of the density detection sensitivity is prevented by preventing a blank region from being included in the noticed pixel, for such a small selected region (region having a high autocorrelation) that the noticed pixel disappears if an edge portion having the width of the predetermined number of pixels is removed from the selected region, the noticed pixel itself is assured even if the density detection sensitivity drops. Consequently, a high degree of accuracy in color tone control can be assured.

If a noticed pixel is set from both sides of automatic setting in accordance with an objective reference by a computer and manual setting in accordance with the subject based on the experience of the operator, then a noticed pixel which includes an intention of the operator and is objectively effective is set. Consequently, the liking of the operator can be reflected on the color tone control.

Further, where a color mixture halftone density corresponding to an image line ratio for each ink supplying unit width for each ink color in the printing picture in the present cycle is determined based on a corresponding relationship between halftone dot area ratios and color mixture halftone densities for each ink color and then the color mixture halftone density corresponding to the image line ratio is set as a target color mixture halftone density, color tone control can be started at a point of time immediately after the operation is started. Consequently, paper loss can be reduced.

Further, it is possible immediately after starting of printing to perform color tone control for particular noticed pixels of the picture without waiting that an OK sheet is printed. Furthermore, where also an ICC profile can be acquired in addition to kcmy halftone dot area ratio data of a printing object picture, the color tone can be controlled based on the ICC profile obtained from a printing requesting source or the like, and consequently, a printed matter of a color tone desired by the printing requesting source or the like can be obtained readily.

Where the actual color coordinate or a color difference between the actual color coordinate value and the target color coordinate value is displayed on a display apparatus, it can be recognized intuitively by the operator by which level colors coincide with each other.

The above and other objects, features and advantages of the present invention will become apparent from the following description and the appended claims, taken in conjunction with the accompanying drawings in which like parts or elements denoted by like reference symbols.

### BRIEF DESCRIPTION OF THE DRAWINGS

FIG. 1 is a schematic view showing a general configuration of an offset rotary press for newspapers according to a first embodiment of the present invention;

FIG. 2 is a functional block diagram showing a color tone controlling function of an arithmetic operation section shown in FIG. 1;

FIGS. 3(a) to 3(d) are diagrammatic views showing printing faces and illustrating automatic selection of a noticed pixel according to the first embodiment of the present invention;

FIG. 4 is a diagrammatic view showing a printing face and illustrating automatic selection of a noticed pixel according to the first embodiment of the present invention;

FIGS. 5(a) to 5(d) are diagrammatic views showing printing faces and illustrating manual selection of a noticed pixel according to the first embodiment of the present invention;

FIGS. 6 and 7 are flow charts illustrating a processing flow for color tone control by an arithmetic operation apparatus shown in FIG. 1;

FIG. 8 is a map for coordinating monochromatic halftone densities and halftone dot area ratios with each other;

FIG. 9 is a map for coordinating solid densities, halftone dot area ratios and monochromatic halftone densities with one another;

FIG. 10 is a flow chart illustrating a processing flow for color tone control according to a second embodiment of the present invention;

FIG. 11 is a flow chart illustrating a processing flow for color tone control according to a third embodiment of the present invention; and

FIG. 12 is a diagrammatic view illustrating a subject to be solved by the present invention.

### DESCRIPTION OF THE PREFERRED EMBODIMENTS

In the following, preferred embodiments of the present invention are described with reference to the accompanying drawings.

### A. First Embodiment

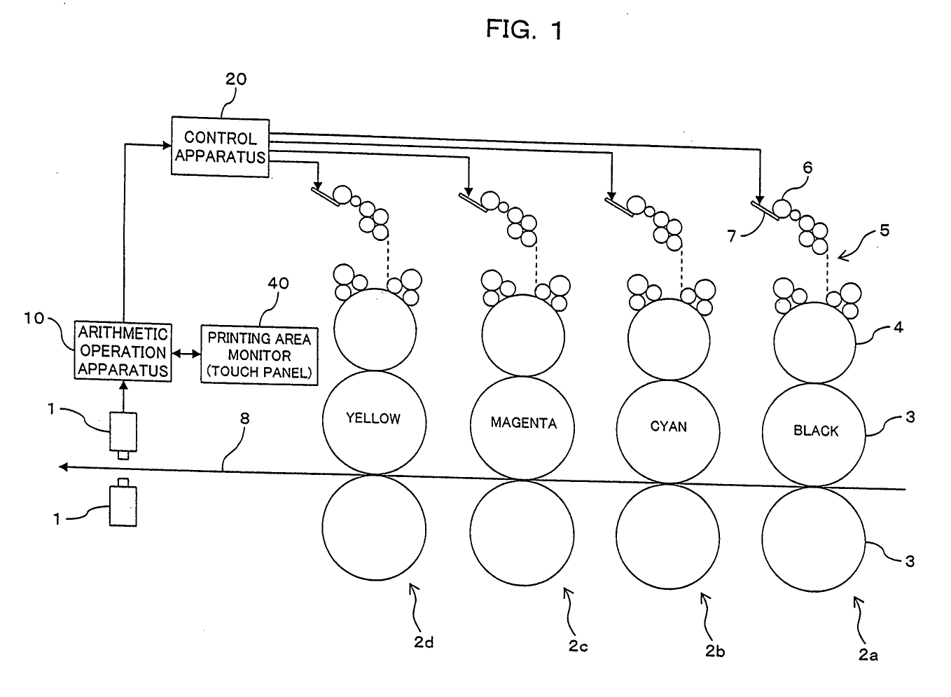

FIG. 1 shows a general configuration of an offset rotary press for newspapers according to a first embodiment of the present invention. The offset rotary press for newspapers of the present embodiment is a double-sided printing press for multi-color printing and includes printing units 2a, 2b, 2c and 2d disposed for different ink colors [black (k), cyan (c), magenta (m) and yellow (y)] along a transport path of a printing sheet 8. In the present embodiment, each of the printing units 2a, 2b, 2c and 2d includes an ink supplying apparatus of the ink key type which includes a plurality of ink keys 7 and an ink fountain roller 6. In the ink supplying apparatus of the type described, the ink supplying amount can be adjusted by the gap amount (the gap amount is hereinafter referred to as ink key opening) of each of the ink keys 7 from the ink fountain roller 6. The ink keys 7 are juxtaposed in the printing widthwise direction, and the ink supplying amount can be adjusted in a unit of the width of each of the ink keys 7 (the ink supplying unit width by each ink key 7 is hereinafter referred to as key zone). The ink whose supplying amount is adjusted by each ink key 7 is kneaded to a suitable degree to form a thin film in an ink roller group 5 and then supplied to a printing surface of a printing cylinder 4. Then, the ink sticking to the printing face is transferred as a picture to the printing sheet 8 through a blanket cylinder 3. It is to be noted that, though not shown in FIG. 1, since the offset rotary press for newspapers of the present embodiment is for double-sided printing, each of the printing units 2a, 2b, 2c and 2d includes a pair of blanket cylinders 3 disposed across the transport path of the printing sheet 8, and a printing cylinder 4 and an ink supplying apparatus are provided for each of the blanket cylinders 3.

The offset rotary press for newspapers includes a pair of line sensor type IRGB densitometers 1 on the further downstream of the most downstream printing units 2d. Each of the line sensor type IRGB densitometers 1 is a measuring instrument for measuring a color of a picture on the printing sheet 8 as reflection densities (color mixture halftone densities) of I (infrared radiation), R (red), G (green) and B (blue) on a line in the printing widthwise direction. The offset rotary press for newspapers can measure the reflection density over the overall printing sheet 8 or measure the reflection density at an arbitrary position of the printing sheet 8. Since the offset rotary press for newspapers is for double-sided printing, the line sensor type IRGB densitometers 1 are disposed on the opposite front and rear sides across the transport path of the printing sheet 8 so that they can measure the reflection density on the opposite front and rear faces of the printing sheet 8.

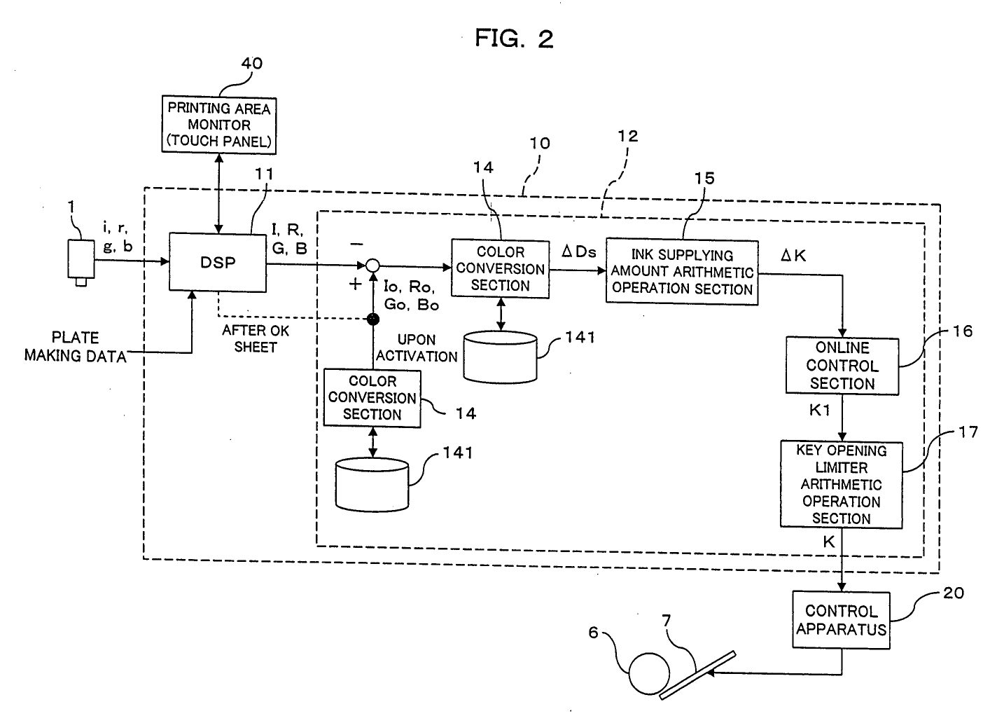

The reflection densities measured by the line sensor type IRGB densitometers 1 are transmitted to an arithmetic operation apparatus (computer) 10. The arithmetic operation apparatus 10 is an apparatus for arithmetically operating control data of the ink supplying amount, and performs arithmetic operation based on the reflection densities measured by the line sensor type IRGB densitometers 1 to arithmetically operate the opening of each of the ink keys 7 for making the color of the picture of the printing sheet 8 coincide with a target color. Here, FIG. 2 is a view showing a general configuration of a picture color tone controlling apparatus for the offset rotary press for newspapers according to the embodiment of the present invention and simultaneously is a functional block diagram showing the arithmetic operation apparatus 10 with attention paid to a color tone controlling function.

Referring to FIG. 2, the arithmetic operation apparatus 10 includes a digital signal processor (DSP) 11 and a personal computer (PC) 12 disposed separately from the printing press. The PC 12 has functions as a color conversion section 14, an ink supplying amount arithmetic operation section 15, an online control section 16 and a key opening limiter arithmetic operation section 17 allocated thereto. The line sensor type IRGB densitometers 1 are connected to the input side of the arithmetic operation apparatus 10, and a control apparatus 20 built in the printing press is connected to the output side of the arithmetic operation apparatus 10. The control apparatus 20 functions as ink supplying amount adjuster (ink supplying amount adjusting means) for adjusting the ink supplying amount for each of the key zones of the ink keys 7. The control apparatus 20 controls an opening/closing apparatus not shown for opening and closing each of the ink keys 7 and can adjust the key opening independently for each ink key 7 of each of the printing units 2a, 2b, 2c and 2d.

Further, a display apparatus (printing area monitor) 40 for displaying a printing picture to be printed on paper is connected to the arithmetic operation apparatus 10, and the printing area monitor 40 has a function as a touch panel. The touch panel 40 can be used to display a printing surface of the printing sheet 8 whose image is picked up by the line sensor type IRGB densitometer 1 and select an arbitrary region on the printing surface with a finger.

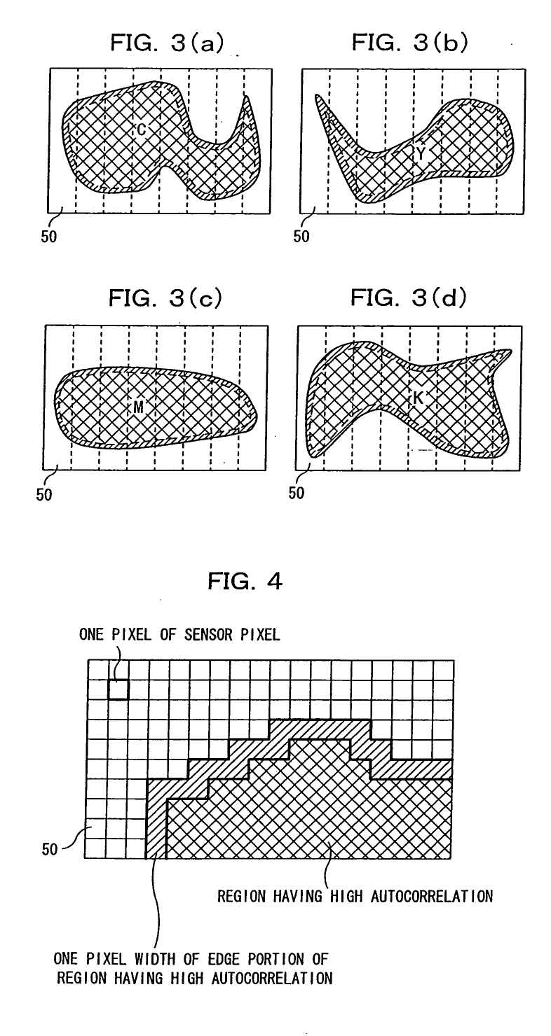

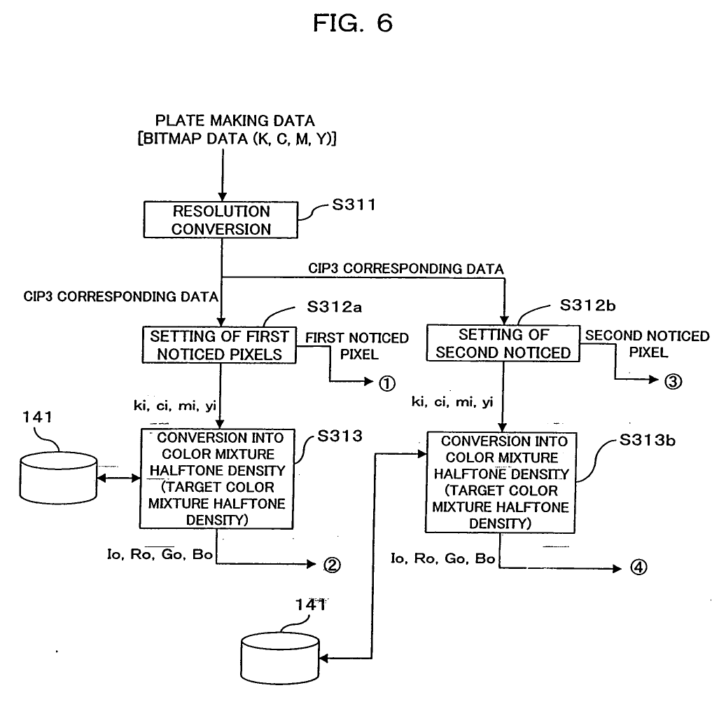

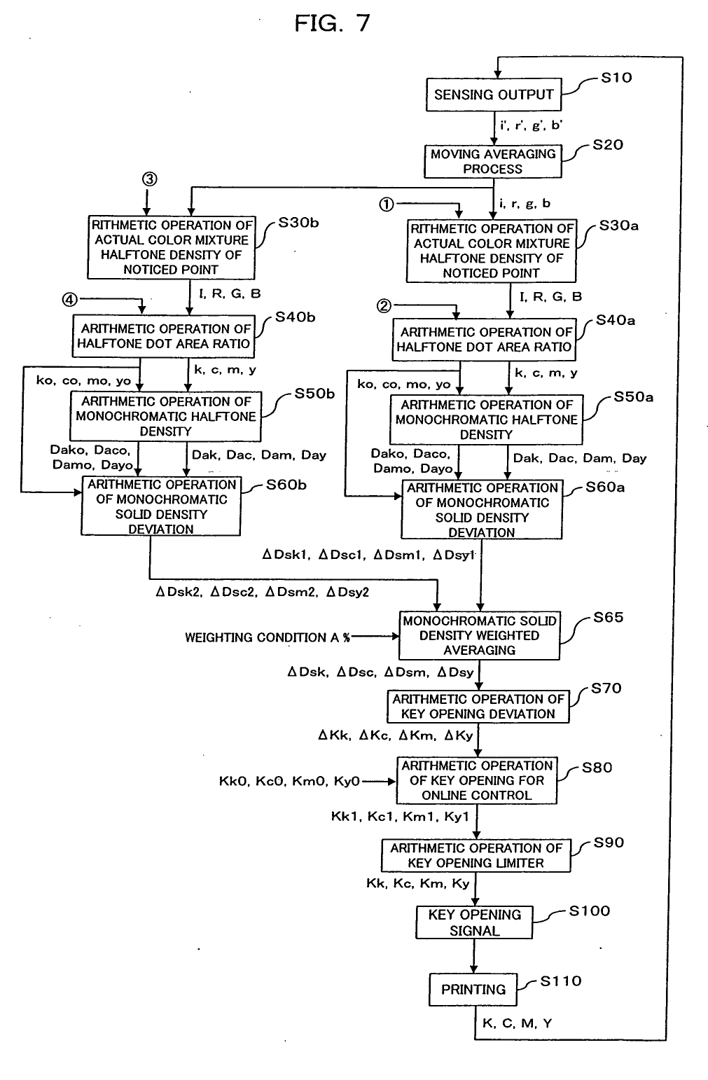

In the following, processing contents of color tone control by the arithmetic operation apparatus 10 are described. FIGS. 3(a) to 5(d) illustrate automatic setting of a noticed pixel which is performed prior to the color tone control, and FIGS. 6 and 7 illustrate a processing flow of the color tone control by the arithmetic operation apparatus 10.

First, a noticed pixel setting method which is performed prior to the color tone control is described principally with reference to FIGS. 3(a) to 5(d).

While the setting of a noticed pixel is performed through a predetermined function (noticed pixel setter or noticed pixel setting means) in the DSP 11 of the arithmetic operation apparatus 10, the DSP 11 in the present embodiment includes, as the noticed pixel setter, a function (noticed pixel automatic setter or noticed pixel automatic setting means) for automatically setting a noticed pixel and another function (noticed pixel manual setter or noticed pixel manual setting means) for setting a noticed pixel in response to a manual input of an operator. Thus, the DSP 11 performs a color tone controlling process based on a noticed pixel set by the noticed pixel automatic setter and another noticed pixel set by the noticed pixel manual setter.

First, the noticed pixel automatic setter is described. Plate making data are inputted in advance to the arithmetic operation apparatus 10, and the DSP 11 of the arithmetic operation apparatus 10 selects a region which exhibits a high autocorrelation with regard to each ink color for each ink supplying unit width when the printing picture is divided with the ink supplying unit width from kcmy halftone dot area ratio data obtained based on the plate making data. Then, the DSP 11 automatically removes, for each color, an edge portion from the selected region of the color by a predetermined number of pixels and sets the resulting region as a noticed pixel to be used as a reference region upon controlling corresponding to the ink color (this function corresponds to the noticed pixel automatic setter which is one of the noticed pixel setter). Here, the ink supplying unit width of the ink supplying apparatus is the key width (key zone) of each ink key if the ink supplying apparatus is an ink key apparatus, but is the pump width of each digital pump if the ink supplying apparatus is a digital pump apparatus.

It is to be noted that, while the plate making data are given as bitmap data, upon setting of a noticed pixel, the bitmap data are first converted into low resolution data corresponding to CIP3 data in accordance with a format of the printing press and then processed in such a pixel unit of a sensor as described below.

In particular, a region which has a high autocorrelation with regard to each ink color particularly is a region whose autocorrelation sensitivity H is higher than a predetermined value set in advance and is a region of a pixel unit of the sensor (IRGB densitometer) 1. The pixel unit of the sensor is a minimum unit in resolution of the sensor (IRGB densitometer) 1. More particularly, an aggregate of a large number of pixels of the plate making data corresponds to one pixel (one block) of the sensor pixel unit. For example, if the CIP3 low resolution data have a resolution of 50.8 dpi and the resolution of one block of the sensor is 2.54 dpi, then a region of the plate making data including 20 pixels in the vertical direction and 20 pixels in the transverse direction (including 20×20=400 pixels as represented by pixel units of the plate making data) forms one pixel unit of the sensor pixel unit.

The autocorrelation sensitivity H, for example, the autocorrelation sensitivity Hc of cyan, can be represented, using pixel area ratio data (c, m, y, k), by “Hc=c²/(c+m+y+k)”. The value of the autocorrelation sensitivity Hc is compared with a reference autocorrelation sensitivity value (predetermined value) Ho set in advance, and if the autocorrelation sensitivity Hc is higher than the reference autocorrelation sensitivity value Ho, then the region is decided to be a region which has a high autocorrelation with regard to cyan. Also with regard to the ink of any other color, the value of the autocorrelation sensitivity H is calculated and individually compared with the reference autocorrelation sensitivity value (predetermined value) Ho set in advance.

It is to be noted that the reference autocorrelation sensitivity value Ho can be set by an inputting operation of an operator. Therefore, it is possible to set the reference autocorrelation sensitivity value Ho to a rather high value to set a noticed pixel restrictively only for those regions which have a considerably high autocorrelation such that, although the number of noticed pixel regions is comparatively small, the density detection sensitivity is raised from a point having a high tone of the pertaining ink to raise the accuracy in color tone control or to set the reference autocorrelation sensitivity value Ho to a rather low value to set a noticed pixel also for regions which do not have a very high autocorrelation such that, although the density detection sensitivity is comparatively low, a comparatively great number of noticed pixel regions are used to raise the accuracy in color tone control. Naturally, a recommended value for the reference autocorrelation sensitivity value Ho (for example, an autocorrelation average value over the overall picture) is inputted in advance so that an operator who does not have much skill can use the recommended value. Further, although the reference autocorrelation sensitivity value H₀ is set so as to have a value common to the ink colors in principle, alternatively the reference autocorrelation sensitivity value H₀ may have different values set to the different colors.

If those regions which have a high autocorrelation are selected for each ink color in this manner, then a region having a high autocorrelation is obtained for each ink color on the plate making face 50 as seen in FIGS. 3(a) to 3(d). If such regions having a high autocorrelation as just described are set as they are as noticed pixels, then only ink of a certain color may sometimes be printed only by a small amount in a block while most part of the block is blank. This drops the density detection sensitivity and gives rises to a drop of the accuracy in color tone control. If some displacement appears between a target image position and a current image position particularly when the printing speed rises high or upon pastering (automatic splicing), then the accuracy in color tone control may drop significantly.

Therefore, taking notice of the fact that there is the possibility that an edge portion of an outer periphery of a region having a high autocorrelation in this manner may be contiguous to a blank portion on which no color is printed, an edge portion indicated by slanting lines is removed from a region having a high autocorrelation and the remaining portion of the region indicated, for example, by a broken line in each of FIGS. 3(a) to 3(d) is set as a noticed pixel. Here, as seen from an enlarged view of FIG. 4, a region (indicated by crossing slanting lines) formed by removing a region (indicated by slanting lines) of a width of one pixel of the sensor pixel unit along the edge portion of the region having a high autocorrelation is set as a noticed pixel.

It is to be noted that the region to be removed from the edge portion of a region having a high autocorrelation is not limited to a region of the width of one pixel of the sensor pixel unit. However, although such removal of an edge portion is performed in order to suppress possible inclusion of a blank portion in a noticed pixel to suppress a drop of the density detection sensitivity thereby to prevent a drop of the accuracy in color tone control, since the removed edge portion is excluded from the noticed pixel, the area of the noticed pixel decreases as much, and this may possibly give rise to a drop of the accuracy in color tone control. Taking these points into consideration, in order to assure a high degree of accuracy in color tone control, preferably a region of a width of only one pixel of the sensor pixel unit is removed from an edge portion.

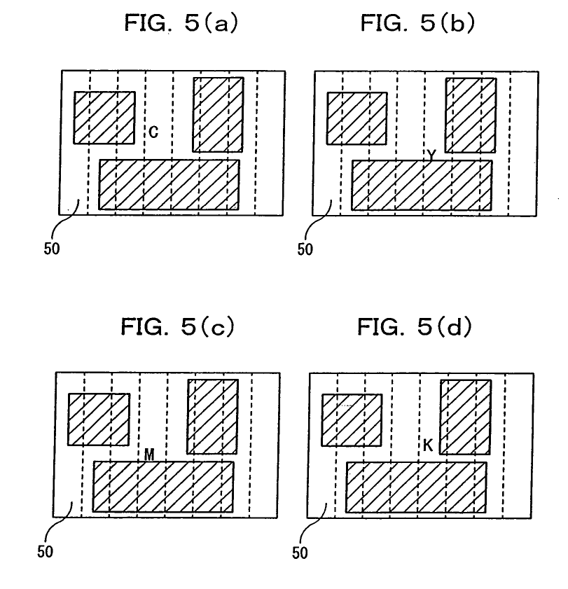

On the other hand, the operator can use a finger to select, as a noticed pixel, an arbitrary region on a printing face (preferably a printing face of the plate making face 50 based on plate making data) displayed on the printing area monitor 40 formed as a touch panel. The manual setting of a noticed pixel is performed for each ink color, for example, as indicated by slanting lines in FIGS. 5(a) to 5(d). A function of the arithmetic operation apparatus 10 and the printing area monitor 40 for such manual setting of a noticed pixel as just described corresponds to the noticed pixel manual setter which is one of the noticed pixel setter. Also in the manual setting of a noticed pixel, a noticed pixel is set in a sensor pixel unit.

While noticed pixels can be set in two systems of a noticed pixel (first noticed pixel) set automatically by the noticed pixel automatic setter and another noticed pixel (second noticed pixel) set manually by the noticed pixel manual setter in this manner, in actual color tone control, control amounts based on the noticed pixels are averaged to set a control amount and the control is performed based on the set control amount. In short, while details are hereinafter described, a solid density deviation for each ink is used for the color tone control. Such solid density deviations are calculated individually based on the first noticed pixel and the second noticed pixel, and the two solid density deviations are weighted averaged in accordance with weights set in advance. Then, the ink supplying amount is adjusted for each ink supplying unit width based on the solid density deviation obtained by the weighted averaging to perform color tone control.

To this end, the arithmetic operation apparatus 10 has a function (weighting setter or weighting setting means) for setting a weighting condition for such weighted averaging such that an operator can arbitrarily set a weighting condition using a keyboard or the like provided for the arithmetic operation apparatus 10. For example, if the weighting condition for the second noticed pixel to be set manually is set to 0 percent, then the solid density deviation is calculated and the color tone control is performed based only on the first noticed pixel set automatically. On the other hand, if the weighting condition for the second noticed pixel to be set manually is set to 100 percent, then the solid density deviation is calculated and the color tone control is performed based only on the second noticed pixel set manually.

Naturally, if the weighting condition for the second noticed pixel to be set manually is set to a suitable value between 0 percent and 100 percent, then the color density deviation is calculated and the color tone control is performed at the ratio of the set value. If the weighting condition for the second noticed pixel is set to 50%, then color tone control is performed using a solid density deviation calculated by simple averaging of the solid density deviation based on the first noticed pixel and the solid density deviation based on the second noticed pixel.

After the setting of noticed pixels is performed in this manner, the target color mixture halftone density for each ink supplying unit width for each noticed pixel when the printing picture is divided with the ink supplying unit width is set based on the pattern information of the plate making data (this function is defined as color mixture halftone density setter or color mixture halftone density setting means).

In the following, a color tone controlling process is described with reference to FIGS. 6 and 7.

Here, since plate making data [page information of a newspaper transmitted in the form of bitmap data (1 bit-Tiff plate making data) or CIP3 data corresponding to 50.8 dpi or equivalent resolution conversion data (data obtained by conversion of 1 bit-Tiff data of 1,200 dpi or 2,400 dpi into 8 bit-Tiff data of 50 dpi) from the head office of the newspaper company to the printing factory] are inputted (received by receiver), at step S311 of FIG. 6, the received bitmap data are converted into low resolution data corresponding to CIP3 data according to the format of the printing press, and the low resolution data are used as pixel area ratio data. Although the resolution conversion process just described is performed in order to achieve compatibility with popular CIP3 data, it is otherwise possible to use the bitmap data themselves as pixel area ratio data in a later process.

At step S312a, a noticed pixel (first noticed pixel) corresponding to each ink color is automatically set for each ink supplying unit width in such a manner as described above.

At step S313a, a conversion table recorded in a database 141 is used to convert the halftone dot area ratios ki, ci, mi, yi of the noticed pixels of the ink colors set automatically into color mixture halftone densities (this function is defined as converter or conversion means), and the resulting color mixture halftone densities are set as target color mixture halftone densities Ioa, Roa, Coa, Boa, respectively.

In parallel to steps S312a and 313a, at step S312b, a noticed pixel (second noticed pixel) corresponding to each ink color is set manually for each ink supplying unit width in such a manner as described above. Then at step S313b, a conversion table recorded in the database 141 is used to convert the halftone dot area ratios ki, ci, mi, yi of the noticed pixels of the ink colors set manually into color mixture halftone densities (this function is defined as converter or conversion means), and the resulting color mixture halftone densities are set as target color mixture halftone densities Ioh, Roh, Coh, Boh, respectively.

After the target color mixture halftone densities Io, Ro, Co, Bo are set in such a manner as described above, processes at steps beginning with step S10 are executed repetitively as seen in FIG. 7. First, at step S10, the line sensor type IRGB densitometer 1 measures the reflected light amounts i′, r′, g′, b′ of each of the pixels on the overall face of the overall printing sheet 8. The reflected light amounts i′, r′, g′, b′ of the pixels measured by the IRGB densitometer 1 are inputted to the DSP 11.

The DSP 11 performs, at step S20, moving averaging in a unit of a predetermined number of prints with regard to the reflected light amounts i′, r′, g′, b′ of the pixels to calculate reflected light amounts i, r, g, b of the pixels from which noise components are removed.

Then at step S30a, the DSP 11 uses the reflected light amounts i, r, g, b of the pixels arithmetically operated at step S20 to arithmetically operate actual color mixture halftone densities I, R, G, B of the first noticed pixels of the individual colors, and then at step S30b, the DSP 11 uses the reflected light amounts i, r, g, b of the pixels arithmetically operated at step S20 to arithmetically operate actual color mixture halftone densities I, R, G, B of the second noticed pixels of the individual colors (the processing function at steps S10 S20, S30a and S30b is defined as actual color mixture halftone density measurer (measuring means)).

The DSP 11 arithmetically operates target color mixture halftone densities Io, Ro, Co, Bo from the reflected light amounts i, r, g, b of the noticed points of the printing plate image and reflected light amounts of a blank portion of the printing plate image, and arithmetically operates actual color mixture halftone densities I, R, G, B from the reflected light amounts i, r, g, b of the noticed points and the reflected light amounts of the blank portion of the printing sheet (actually printed sheet) 8. It is to be noted that, since a noticed pixel basically is an aggregate of a plurality of pixels, each of the reflected light amounts i, r, g, b is calculated by averaging among the plural pixels which form the noticed pixel. For example, where the reflected light amount of infrared radiation from a blank portion is represented by ip and the average reflected light amount of the infrared radiation within a key zone is represented by ik, the actual color mixture halftone density I of the infrared radiation is determined as I=log (ip/ik). The actual color mixture halftone densities I, R, G, B for each key zone determined by the DSP 11 are inputted to the color conversion section 14 of the PC 12.

The color conversion section 14 performs processes at steps S40a, S50a and S60a and processes at steps S40b, S50b and S60b.

First, at step S40a, the color conversion section 14 arithmetically operates the halftone dot area ratios for the individual ink colors corresponding to the target color mixture halftone densities Io, Ro, Co, Bo for the first noticed pixels of the individual colors set at step S313a and the actual color mixture halftone densities I, R, G, B for the first noticed pixels of the individual colors arithmetically operated at step S30a. Then, at step S40b, the color conversion section 14 arithmetically operates the halftone dot area ratios for the individual ink colors corresponding to the target color mixture halftone densities Io, Ro, Co, Bo for the second noticed pixels of the individual colors set at step S313b and the actual color mixture halftone densities I, R, G, B for the second noticed pixels of the individual colors arithmetically operated at step S30b. In the arithmetic operation, the database 141 is used, and the halftone dot area ratios of the individual ink colors corresponding to the target color mixture halftone densities Io, Ro, Co, Bo are arithmetically operated as target halftone dot area ratios ko, co, mo, yo, and the halftone dot area ratios of the individual colors corresponding to the actual color mixture halftone densities I, R, G, B are arithmetically operated as actual halftone dot area ratios k, c, m, y. At steps S40a and S40b, the function of arithmetically operating the target halftone dot area ratios is defined as target halftone dot area ratio arithmetic operation means, and the function of arithmetically operating the actual halftone dot area ratios is defined as actual halftone dot area ratio arithmetic obtainer (arithmetic operation means).

Thereafter, at step S50a, the color conversion section 14 arithmetically operates monochromatic halftone densities of the individual ink colors corresponding to the target halftone dot area ratios ko, co, mo, yo and the actual halftone dot area ratios k, c, m, y calculated at step S40a. The function of arithmetically operating the monochromatic halftone densities (target monochromatic halftone densities) of the individual ink colors corresponding to the target halftone dot area ratios is defined as target monochromatic halftone density arithmetic obtainer (arithmetic operation means), and the function of arithmetically operating the monochromatic halftone densities (actual monochromatic halftone densities) of the individual ink colors corresponding to the actual dot area ratios is defined as actual monochromatic halftone density arithmetic obtainer (arithmetic operation means).

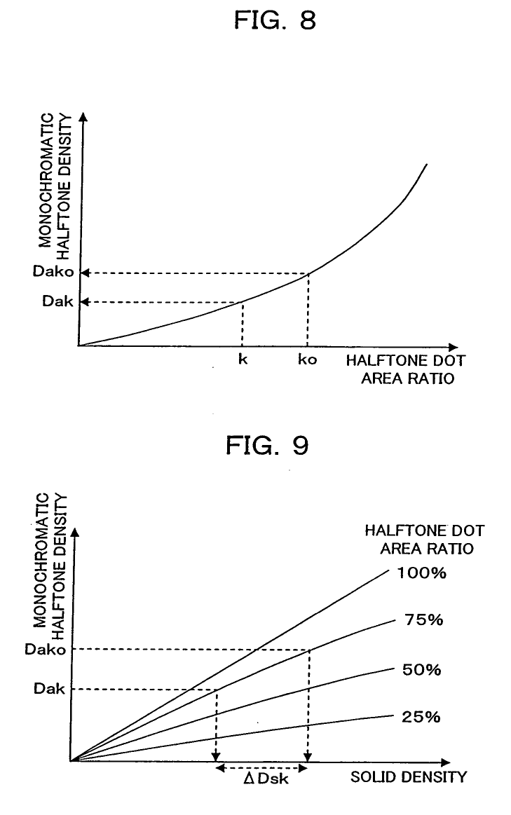

Further, at step S50b, the color conversion section 14 arithmetically operates monochromatic halftone densities of the individual ink colors corresponding to the target halftone dot area ratios ko, co, mo, yo and the actual halftone dot area ratios k, c, m, y calculated at step S40b. For such arithmetic operation, such a map as illustrated in FIG. 8 is used. FIG. 8 shows an example of a map obtained by plotting the monochromatic halftone densities actually measured when the halftone dot area ratio is varied as a characteristic curve and is produced from data measured in advance. In the example illustrated in FIG. 8, the target halftone dot area ratio ko and the actual halftone dot area ratio k of the black color are applied to the map to determine a target monochromatic halftone density Dako and an actual monochromatic halftone density Dak, respectively, from the characteristic curve in the map. The color conversion section 14 determines target monochromatic halftone densities Dako, Daco, Damo, Dayo and the actual monochromatic halftone densities Dak, Dac, Dam, Day of the individual ink colors in this manner.

Then, at step S60a, the color conversion section 14 arithmetically operates solid density deviations ΔDsk1, ΔDsc1, ΔDsm1, ΔDsy1 of the individual ink colors corresponding to the deviations between the target monochromatic halftone densities Dako, Daco, Damo, Dayo and the actual monochromatic halftone densities Dak, Dac, Dam, Day of the first noticed pixels of the individual colors. Further, at step S60b, the color conversion section 14 arithmetically operates solid density deviations ΔDsk2, ΔDsc2, ΔDsm2, ΔDsy2 of the individual ink colors corresponding to the deviations between the target monochromatic halftone densities Dako, Daco, Damo, Dayo and the actual monochromatic halftone densities Dak, Dac, Dam, Day of the second noticed pixels of the individual colors. The function of arithmetically operating the solid density deviations of the ink colors is defined as solid density deviation arithmetic obtainer (arithmetic operation means).

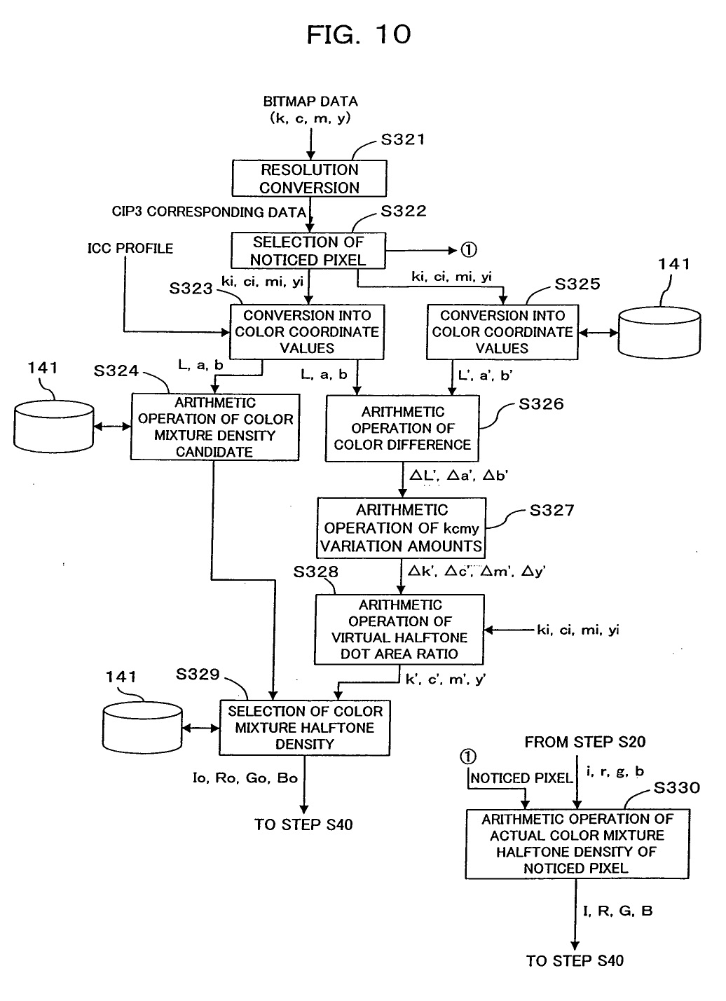

It is to be noted that the solid density relies also upon the halftone dot area ratio, and where the monochromatic halftone density is equal, the solid density decreases as the halftone dot area ratio increases. Therefore, the color conversion section 14 performs the arithmetic operation using such a map as illustrated in FIG. 9. FIG. 9 shows an example of a map obtained by plotting the monochromatic halftone densities actually measured when the monochromatic solid density is varied as a characteristic curve for different halftone dot area ratios, and is produced from data measured in advance. The color conversion section 14 selects one of the characteristic curves which correspond to the target halftone dot area ratios ko, co, mo, yo from within the map illustrated in FIG. 6 for each ink color, and applies the target monochromatic halftone densities Dako, Daco, Damo, Dayo and the actual monochromatic halftone densities Dak, Dac, Dam, Day to the selected characteristic curves to determine the solid density deviations ΔDsk1, ΔDsc1, ΔDsm1, ΔDsy1 and ΔDsk2, ΔDsc2, ΔDsm2, ΔDsy2. In the example illustrated in FIG. 9, where the target halftone dot area ratio ko of the black color is 75%, the target monochromatic halftone density Dako and the actual monochromatic halftone density Dak are applied to the map to determine the solid density deviation ΔDsk of the black color from the 75% characteristic curve in the map.

After the solid density deviations ΔDsk1, ΔDsc1, ΔDsm1, ΔDsy1 based on the first noticed pixels and the solid density deviations ΔDsk2, ΔDsc2, ΔDsm2, ΔDsy2 based on the second noticed pixels are calculated in this manner, both solid density deviations are weighted averaged in accordance with weighting conditions set in advance to acquire solid density deviations ΔDsk, ΔDsc, ΔDsm, ΔDsy. The solid density deviations ΔDsk, ΔDsc, ΔDsm, ΔDsy can be calculated, where the weighting conditions for the second noticed pixels set manually are set to A percent, in accordance with the following expressions:
ΔDsk=(1−A)·ΔDsk1+A·ΔDsk2
ΔDsc=(1−A)·ΔDsc1+A·ΔDsc2
ΔDsm=(1−A)·ΔDsm1+A·ΔDsm2
ΔDsy=(1−A)·ΔDsy1+A·ΔDsy2

The solid density deviations ΔDsk, ΔDsc, ΔDsm, ΔDsy of the individual ink colors arithmetically operated by the color conversion section 14 are inputted to the ink supplying amount arithmetic operation section 15. At step S70, the ink supplying amount arithmetic operation section 15 arithmetically operates key opening deviation amounts ΔKk, ΔKc, ΔKm, ΔKy corresponding to the solid density deviations ΔDsk, ΔDsc, ΔDsm, ΔDsy, respectively. The key opening deviation amounts ΔKk, ΔKc, ΔKm, ΔKy are increasing or decreasing amounts from the key openings Kk0, Kc0, Km0, Ky0 at present (key openings Kk, Kc, Km, Ky outputted to the control apparatus 20 of the printing press by the process at step S100 in the preceding operation cycle) of the individual ink keys 7, and the ink supplying amount arithmetic operation section 15 performs the arithmetic operation using the known API function (auto-preset inking function). The API function is a function indicating a relationship between image line ratios A (Ak, Ac, Am, Ay) and the key openings K (Kk, Kc, Km, Ky) for each key zone to establish a reference density. The image line ratios A determined at step S0 may be used as such. More particularly, the ink supplying amount arithmetic operation section 15 determines the ratios kd (kd=ΔDs/Ds) of the solid density deviations ΔDs (ΔDsk, ΔDsc, ΔDsm, ΔDsy) to reference densities Ds (Dsk, Dsc, Dsm, Dsy) and the key opening K for obtaining a reference density with respect to each of the image line ratios A using the API function. Then, the ink supplying amount arithmetic operation section 15 determines the product of the image line ratios A and the key openings K to determine key opening deviation amounts ΔK (ΔK=kd×K) for reducing the solid density deviations ΔDs to zero.

Then, at step S80, the online control section 16 corrects the key opening deviation amounts ΔKk, ΔKc, ΔKm, ΔKy arithmetically operated by the color conversion section 14 taking the dead times from the printing units 2a, 2b, 2c and 2d to the line sensor type IRGB densitometer 1, reaction times of the ink keys 7 per unit time and the printing speed into consideration. In the correction, a time delay after a key opening signal is inputted until a corresponding ink key 7 moves to change the key opening thereby to change the ink amount to be supplied to the printing sheet and the variation of the ink amount appears as a variation of the reflected light amount on the line sensor type IRGB densitometer 1 is taken into consideration. For such an online feedback control system which involves considerable dead time as described above, for example, PI control with dead time compensation, fuzzy control or robust control is optically applied. The online control section 16 adds the key openings Kk0, Kc0, Km0, Ky0 at present to the key opening deviation amounts (online control key opening deviations) ΔKk, ΔKc, ΔKm, ΔKy to determine online control key openings Kk1, Kc1, Km1, Ky1 and inputs the determined online control key openings Kk1, Kc1, Km1, Ky1 to the key opening limiter arithmetic operation section 17.

At step S90, the key opening limiter arithmetic operation section 17 performs correction of restricting upper limit values to the online control key openings Kk1, Kc1, Km1, Ky1 arithmetically operated by the online control section 16. This is a process for restricting the key openings from increasing abnormally particularly arising from an estimated error of the color conversion algorithm (processes at steps S40, S50 and S60) in a low image line ratio region. Then at step S100, the key opening limiter arithmetic operation section 17 transmits the key openings Kk, Kc, Km, Ky whose upper limit values are restricted as key opening signals to the control apparatus 20 of the printing press.

At step S110, the control apparatus 20 adjusts the ink key openings 7 of the printing units 2a, 2b, 2c and 2d based on the key opening signals Kk, Kc, Km, Ky received from the arithmetic operation apparatus 10 (the function of performing the processes at steps S70 to S110 is defined as ink supplying amount adjuster (adjusting means)). Consequently, the ink supplying amounts of the ink colors are controlled so as to conform to a target color tone for each key zone.

According to the color tone controlling method and apparatus of the present embodiment, when a noticed pixel which is to be used as a reference region upon controlling corresponding to each ink color is to be set, a region which has a high autocorrelation with regard to each ink color is selected, and a region obtained by removing an edge portion (that is, a portion contiguous to a blank region) of the pertaining ink color having a width of one pixel of a sensor pixel from the selected region is set as a noticed pixel. Consequently, a drop of the density detection sensitivity can be prevented, and the accuracy in color tone control can be assured. Therefore, even if some displacement appears between a target image position and a current image position when the printing speed rises high or upon pastering (automatic splicing), a significant drop of the accuracy in color tone control can be prevented.

Besides, since a noticed pixel can be set from both sides of automatic setting in accordance with an objective reference by the control apparatus 20 and manual setting in accordance with the subject based on the experience of the operator, a noticed pixel which includes an intention of the operator and is objectively effective is set. Consequently, the liking of the operator can be reflected on the color tone control. Further, by setting of a weighting condition, the intension of the operator can be reflected at an appropriate rate.

Accordingly, if the weighting condition for the second noticed pixel manually set is set to a value equal to or near to 100 percent, then color tone control (ink supplying amount control) on which an intention of an operator is reflected strongly can be carried out. The color tone control is suitable particularly where the operator is skilled. On the other hand, when control is to be carried out without depending much upon the operator, if the weighting condition for the second noticed pixel set manually is set to a value equal to or near to 0 percent, then appropriate color tone control (ink supplying amount control) which is based on a standard noticed pixel set automatically in accordance with a subjective reference by the control apparatus 20 can be implemented.

Particularly, since those noticed pixels which are set automatically are all pixels in a region in which the autocorrelation sensitivity value H is higher than the reference autocorrelation sensitivity value H₀ except an edge portion, a wide noticed pixel region can be assured, and a high degree of accuracy in color tone control can be assure. Further, since the reference autocorrelation sensitivity value Ho is adjustable, a suitable reference autocorrelation sensitivity value H₀ can be set in accordance with a control object to raise the accuracy in control.

Then, after actual printing is entered, it becomes possible immediately after starting of printing to perform color tone control accurately for particular noticed points of the picture without waiting that an OK sheet is printed. Accordingly, the period of time before an OK sheet is obtained can be further reduced thereby to reduce loss paper. Particularly where a pixel having a maximum autocorrelation with regard to the halftone dot area ratio of the pixels for each color is set as a noticed point, since the sensing sensitivity is enhanced, adjustment to a desired color tone can be performed rapidly.

It is to be noted that, while, in the embodiment described above, when a noticed pixel is to be automatically set, a region having a high autocorrelation is selected for each ink color and an edge portion of the pertaining ink color having a width of a predetermined number of pixels is removed from the selected region, if the edge portion having the width of the predetermined number of pixels is removed, then the noticed pixels may possibly disappear. Therefore, the picture color tone controlling method and apparatus may be configured otherwise such that a region having a high autocorrelation is selected and, if a noticed pixel remains present even if an edge portion of the pertaining ink color having a width of a predetermined number of pixels is removed from the selected region, then the region formed by removing the edge portion of the width of the predetermined number of pixels from the selected region is set as a noticed pixel of the pertaining ink color, but if no noticed pixel remains present if the edge portion having the width of the predetermined number of pixels is removed from the selected region, then the region itself which exhibits a high autocorrelation is set as a noticed pixel of the pertaining ink color without removing the edge portion from the selected region.

According to this, while a drop of the density detection sensitivity is prevented by removing an edge portion having the predetermined number of pixels from within the selected region to prevent a blank portion from being included in the noticed pixel, for such a small selected region (region having a high autocorrelation) that the noticed pixel disappears if an edge portion having the width of the predetermined number of pixels is removed from the selected region, the noticed pixel itself is assured even if the density detection sensitivity drops, and consequently, a high degree of accuracy in color tone control can be assured.

### B. Second Embodiment

A second embodiment of the present invention is described with reference to FIG. 10. Also in the present embodiment, a noticed pixel is set in a similar manner as in the first embodiment.

It is assumed that, also in the present embodiment, printing data of page information for a newspaper transmitted in the form of bitmap data from the head office of a newspaper company to a printing factory are inputted similarly as in the first embodiment. However, in the present embodiment, as a first difference from the first embodiment, also an ICC profile of an inputting apparatus by which color information of the page has been produced is transmitted in addition to the bitmap data of the page information. At step S321, the bitmap data are converted into low resolution data corresponding to CIP3 data according to the format of the printing press, and at step S322, a noticed point corresponding to each ink color is set for each ink supplying unit width.

It is to be noted that, while processes at steps S322 to S330 are executed for both of a first noticed pixel and a second noticed pixel described hereinabove in connection with the first embodiment, since the processing contents for the first noticed pixel and the second noticed process are similar to each other, they are described as processes executed at common steps below. Further, the contents of a process at step S321 are similar to those at step S311 according to the first embodiment, and the contents of a process at step S322 are similar to those at steps S312a and S312b according to the first embodiment. Therefore, detailed description of the processing contents is omitted herein to avoid redundancy.

At step S323, the ICC profile received from the head office of the newspaper company is used to convert the halftone dot area ratios ki, ci, mi, yi of the noticed points into a color coordinate value L, a, b. Then at step S324, a conversion table stored in the database 141 is used to convert the color coordinate value L, a, b determined at step S323 into a color mixture halftone density. However, since the color mixture halftone density is four-dimensional information while the color coordinate value is three-dimensional information, the color mixture halftone density corresponding to the color coordinate value is not determined uniquely. In order to determine the color mixture halftone density uniquely, some additional information is required. However, from the ICC profile, only three-dimensional information of the color coordinate value can be obtained.

Therefore, in the present embodiment, the halftone dot area ratio data of the printing picture, that is, the halftone dot area ratios ki, ci, mi, yi corresponding to the color coordinate value L, a, b, are utilized to select, in development from such three-dimensional information into four-dimensional information, the most appropriate pieces of four-dimensional information from among a large number of pieces of the four-dimensional information which are regarded as candidates.

First at step S325, the conversion table stored in the database 141 is used to convert the halftone dot area ratios ki, ci, mi, yi of the noticed points into color coordinate values L′, a′, b′. At step S326, color differences ΔL′, Δa′, Δb′ between the color coordinate values L, a, b determined at step S323 and the color coordinate values L′, a′, b′ determined at step S325 are arithmetically operated. Then at step S327, variation amounts Δk′, Δc′, Δm′, Δy′ of the halftone dot area ratios corresponding to the color differences ΔL′, Δa′, Δb′, respectively, are arithmetically operated. The variation amounts of the halftone dot area ratios can be approximated by the following expressions using the variation amounts of the color coordinate values. It is to be noted that a and b in the following expressions are linear approximation coefficients.
Δc′=a11×ΔL′+a12×Δa′+a13×Δb′+bc (1)
Δm′=a21×ΔL′+a22×Δa′+a23×Δb′+bm (2)
Δy′=a31×ΔL′+a32×Δa′+a33×Δb′+by (3)
Δk′=a41×ΔL′+a42×Δa′+a43×Δb′+bk (4)

At step S328, the variation amounts Δk′, Δc′, Δm′, Δy′ determined at step S327 are added to the halftone dot area ratios ki, ci, mi, yi of the noticed points, and the resulting values are set as virtual halftone dot area ratios k′, c′, m′, y′, respectively. At step S329, the virtual halftone dot area ratios k′, c′, m′, y′ are applied to the conversion table recorded in the database 141 to select, from among the color mixture halftone density candidates determined at step S324, those which correspond most to the virtual halftone dot area ratios k′, c′, m′, y′. The selected color mixture halftone densities are set as the target color mixture halftone densities Io, Ro, Co, Bo and are used in the processes at steps beginning with step S40 (steps S40a and S40b in FIG. 7) together with the actual color mixture halftone densities I, R, G, B of the noticed points arithmetically operated at step S330.

According to the present method, since an ICC profile obtained from a printing requesting source or the like can be used to control the color tone, the color tone can be adjusted accurately and easily to a color tone desired by the printing requesting source or the like when compared with alternative color adjustment which is performed through comparison with a proof-sheet as is performed conventionally. Accordingly, with the present method, the appearing amount of paper loss before an OK sheet is obtained can be reduced significantly.

### Third Embodiment

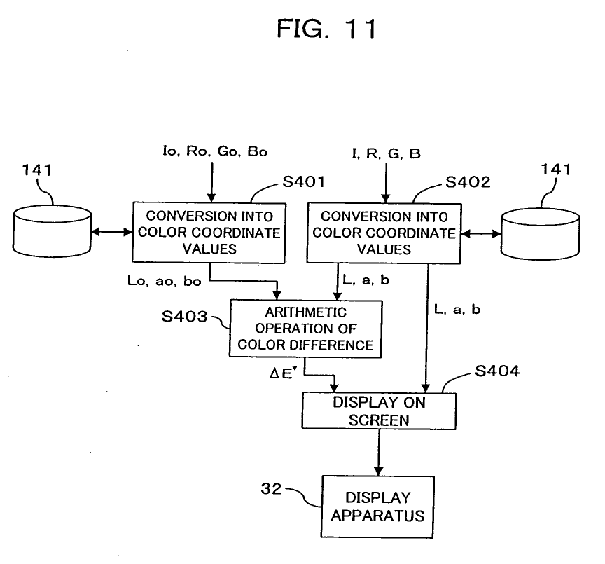

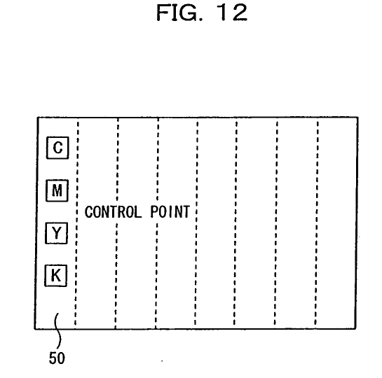

A third embodiment of the present invention is described with reference to FIG. 11. The present embodiment proposes an auxiliary method for color tone control and can be applied additionally to both of the color control methods of the first and second embodiments. It is to be noted that, in the present third embodiment, a noticed pixel is set in a similar manner as in the first embodiment.

At step S401, the conversion table recorded in the database 141 is used to convert the target color mixture halftone densities Io, Ro, Co, Bo into color coordinate values (target color coordinate values) (this function is defined as target color coordinate value arithmetic obtainer (arithmetic operation means)). At step S402, the conversion table is used similarly to convert the actual color mixture halftone densities I, R, G, B into color coordinate values (actual color coordinate values) (this function is defined as actual color coordinate value arithmetic obtainer (arithmetic operation means)). Then at step S403, the color differences ΔE* between the target color coordinate values Lo, ao, bo determined at step S401 and the actual color coordinate values L, a, b determined at step S402 are arithmetically operated in accordance with
ΔE*=√{(Lo−L)²+(ao−a)²+(bo−b)²}
(this function is defined as color difference arithmetic obtainer (arithmetic operation means)). At step S404, the actual color coordinate values L, a, b and the color difference ΔE* are displayed on a display apparatus 32.

Since the L*a*b* calorimetric system is a calorimetric system wherein the coordinates have a linear relationship to the color stimulus of the human being, where the color of a noticed point is represented by the color coordinate values L, a, b or the color difference ΔE* of a noticed pixel from a target color is displayed as in the present method, it can be recognized intuitively by the operator by which level colors coincide with each other. Accordingly, by carrying out the present method additionally to the first and second embodiments, the present method can assist the decision of the operator to achieve more accurate color matching.

D. Others

While several preferred embodiments of the present invention have been described above, the embodiments of the present invention are not limited to those described above.

For example, while, in the embodiments described hereinabove, a noticed pixel is set by automatic setting by a control apparatus and manual setting by an operator and values obtained by the automatic setting and the manual setting are weighted averaged, and the weighting condition for the weighted averaging can be set arbitrarily. However, more simply, the weighting condition may otherwise be set by selection from among three patterns including an automatic setting priority pattern (automatic setting by 100 percent), a manual setting priority pattern (manual setting by 100 percent) and a simple average pattern (automatic setting by 50 percent and manual setting by 50 percent). Or further simply, the weighting condition may be set by selection only from between an automatic setting priority pattern (automatic setting by 100 percent) and a manual setting priority pattern (manual setting by 100 percent). Or, even if automatic setting is adopted, the effects provided by automatic setting described hereinabove can be anticipated.

Further, the first embodiment may use, in addition to the method which uses the database 141 which coordinates halftone doe area ratios and color mixture halftone densities of the individual ink colors with each other, another method may be adopted wherein the known Neugebauer expression which defines a corresponding relationship between halftone dot area ratios and color mixture halftone densities of the individual ink colors is stored in advance and the halftone dot area ratio of each ink color is applied to calculate a color mixture halftone density.

Further, in addition to the method of determining the solid density deviations of the individual ink colors corresponding to the deviations between the target monochromatic halftone densities and the actual monochromatic halftone densities using such a map as illustrated in FIG. 6, also a method is available wherein the known Yule-Nielsen expression which defines a corresponding relationship among halftone dot area ratios, monochromatic halftone densities and solid densities is stored in advance, and a target halftone dot area ratio, an actual halftone dot area ratio and a monochromatic halftone density are applied to the expression to calculate the solid density deviation.

Further, while, in the embodiments, an IRGB densitometer of the line sensor type is used, alternatively an IRGB densitometer of the spot type may be used to scan the printing sheet two-dimensionally.

The present invention is not limited to the embodiment specifically described above, and variations and modifications can be made without departing from the scope of the present invention.

What is claimed is:

1. A picture color tone controlling method for a printing press, comprising:
a noticed pixel setting step of setting, for each of ink supplying unit widths of an ink supplying apparatus when a printing picture is divided with the ink supplying unit width, a noticed pixel which is a reference region upon controlling corresponding to each of ink colors from kcmy halftone dot area ratio data obtained based on plate making picture information, the noticed pixel setting step including selection of a region which has a high autocorrelation for each of the ink colors in a sensor pixel unit of an IRGB densitometer and setting, for each of the ink colors, if the noticed pixel remains present in the selected region even if an edge portion with regard to the pertaining ink color corresponding to predetermined sensor pixels is removed from the selected region, of the remaining region of the selected region from which the edge portion corresponding to the predetermined sensor pixels are removed as the noticed pixel of the pertaining ink color;
a target color mixture halftone density setting step of setting a target color mixture halftone density regarding the noticed pixel for each of the ink colors for each of the ink supplying unit widths;
an actual color mixture halftone density measuring step of measuring an actual color mixture halftone density with regard to the noticed pixel of each of the ink colors for each of the ink supplying unit widths of an actually printed sheet obtained by printing using the IRGB densitometer; and
a color mixture halftone density adjusting step of adjusting the ink supplying amounts for each of the ink supplying unit widths so that the actual color mixture halftone density may approach the target color mixture halftone density.

2. The picture color tone controlling method for a printing press as claimed in claim 1, wherein, at the noticed pixel setting step, if the noticed pixel does not remain when the edge portion with regard to the ink color corresponding to the predetermined sensor pixels is removed from the selected region, then the region which has the high autocorrelation is set as the noticed pixel of the pertaining ink color without removing the edge portion from the selected region.

3. The picture color tone controlling method for a printing press as claimed in claim 2, wherein the color mixture halftone density adjusting step includes:
a target halftone dot area ratio calculation step of calculating a target halftone dot area ratio of each of the ink colors corresponding to the target color mixture halftone density based on a corresponding relationship set in advance between halftone dot area ratios and color mixture halftone densities;
an actual halftone dot area ratio calculation step of determining an actual halftone dot area ratio of each of the ink colors corresponding to the actual color mixture halftone density based on the corresponding relationship between the halftone dot area ratios and the color mixture halftone densities;
a target monochromatic halftone density calculation step of determining a target monochromatic halftone density corresponding to the target halftone dot area ratio based on a corresponding relationship set in advance between the halftone dot area ratios and monochromatic halftone densities;
an actual monochromatic halftone density calculation step of determining an actual monochromatic halftone density corresponding to the actual halftone dot area ratio based on the corresponding relationship between the halftone dot area ratios and the monochromatic halftone densities;
a solid density deviation calculation step of determining, based on a corresponding relationship set in advance among the halftone dot area ratios, the monochromatic halftone densities and solid densities, a solid density deviation corresponding to a deviation between the target monochromatic halftone density and the actual monochromatic halftone density under the target halftone dot area ratio with regard to the noticed pixel; and
a step of adjusting an ink supplying amount for each of the ink supplying unit widths based on the solid density deviation.

4. The picture color tone controlling method for a printing press as claimed in claim 1, wherein, at the noticed pixel setting step, when the edge portion with regard to the pertaining ink color is removed in a unit of a sensor pixel from within the selected region, the edge portion is removed by only one pixel in the sensor pixel unit.

5. The picture color tone controlling method for a printing press as claimed in claim 1, wherein the region which has a high autocorrelation at the noticed pixel setting step is a group of all those pixels which have an autocorrelation higher than a condition set in advance for each of the ink colors, and the noticed pixel setting step is configured as a noticed pixel automatic setting step at which a computer is used to automatically extract the group of pixels.

6. The picture color tone controlling method for a printing press as claimed in claim 5, further comprising a noticed pixel manual setting step at which the noticed pixel is set manually by an operator separately from the noticed pixel automatic setting step, and the target color mixture halftone density setting step, the actual color mixture halftone density measuring step, the target halftone dot area ratio calculation step, the actual halftone dot area ratio calculation step, the target monochromatic halftone density calculation step, the actual monochromatic halftone density calculation step and the solid density deviation calculation step are carried out for both of a first noticed pixel which is the noticed pixel set by the noticed pixel automatic setting step and a second noticed pixel which is the noticed pixel set by the noticed pixel manual setting step to obtain two solid density deviations, and then at the ink supplying amount adjusting step, the ink supplying amount is adjusted for each of the ink supplying unit widths based on the two solid density deviations.

7. The picture color tone controlling method for a printing press as claimed in claim 6, wherein, at the ink supplying amount adjusting step, the solid density deviation obtained with regard to the first noticed pixel and the solid density deviation obtained with regard to the second noticed pixel are weighted averaged in accordance with a weighting condition set in advance, and the ink supplying amount is adjusted for each of the ink supplying unit widths based on the solid density deviation obtained by the weighted averaging.

8. The picture color tone controlling method for a printing press as claimed in claim 1, wherein the target color mixture halftone density setting step includes a step of acquiring the kcmy halftone dot area ratio data, a step of converting a halftone dot area ratio of the noticed pixel obtained as the kcmy halftone dot area radio data into a color mixture halftone density based on a corresponding relationship set in advance between halftone dot area ratios and color mixture halftone densities, and a step of setting the color mixture halftone density obtained by the conversion to the target color mixture halftone density, and at the target color mixture halftone density setting step, the color mixture halftone density of the noticed pixel is set as the target color mixture halftone density whereas, at the actual color mixture halftone density measuring step, the actual color mixture halftone density of the noticed pixel is measured.

9. The picture color tone controlling method for a printing press as claimed in claim 1, wherein the target color mixture halftone density setting step includes a step of acquiring an ICC profile in addition to the kcmy halftone dot area ratio data, a step of converting the halftone dot area ratio of the noticed pixel into a color mixture halftone density using the ICC profile and a device profile of the IRGB densitometer, and a step of setting the color mixture halftone density obtained by the conversion to the target color mixture halftone density, and at the actual color mixture halftone density measuring step, the actual color mixture halftone density of the noticed pixel is measured.

10. The picture color tone controlling method for a printing press as claimed in claim 9, wherein the device profile is a conversion table which defines a corresponding relationship among the halftone dot area ratios, color mixture halftone densities and color coordinate values, and
the step of converting the halftone dot area ratio of the noticed pixels into the color mixture halftone density includes the steps of:
converting the halftone dot area ratio of the noticed pixels into a color coordinate value using the ICC profile;
determining a plurality of candidates for the color mixture halftone density corresponding to the color coordinate values of the noticed pixels using the conversion table;
converting the halftone dot area ratios of the noticed pixels into color coordinate values using the conversion table;
determining a color difference between the two color coordinate values obtained by the conversion performed using the ICC profile and the conversion performed using the conversion table;
arithmetically operating an amount of variation of the halftone dot area ratio corresponding to the color difference;
adding the variation amount to the halftone dot area ratio of the noticed pixels to determine a virtual halftone dot area ratio; and
selecting a candidate corresponding best to the virtual halftone dot area ratio from among the plural candidates for the color mixture halftone density with reference to the conversion table;
the step of converting the halftone dot area ratio of the noticed pixels into the color mixture halftone density setting the selected candidate for the color mixture halftone density as the color mixture halftone density of the noticed pixels.

11. The picture color tone controlling method for a printing press as claimed in claim 8, wherein the step of acquiring kcmy halftone dot area ratio data first acquires bitmap data of a printing object picture and converts the bitmap data into low resolution data corresponding to CIP3 data, and then uses the converted data as the kcmy halftone dot area ratio data.

12. The picture color tone controlling method for a printing press as claimed in claim 1, further comprising the steps of:
determining an actual color coordinate value corresponding to the actual color mixture halftone density of each of the noticed pixels measured by the IRGB densitometer based on a corresponding relationship set in advance between the color mixture halftone densities and color coordinate values;
determining a target color coordinate value corresponding to the target color mixture halftone density based on the corresponding relationship between the color mixture halftone densities and the color coordinate values;
determining a color difference between the actual color coordinate value and the target color coordinate value; and
displaying the actual color coordinate value and/or the color difference on a display apparatus.

13. A picture color tone controlling apparatus for a printing press, comprising:
an ink supplying apparatus for supplying ink for each of divisional regions divided in a printing widthwise direction;
an IRGB densitometer disposed on a feeding line of an actually printed sheet obtained by printing;
noticed pixel setter to set a noticed pixel which is a reference region of controlling procedure corresponding to each of ink colors according to kcmy halftone dot area ratio data obtained based on plate making picture information,
wherein said noticed pixel is selected in each of ink supplying unit widths of said ink supplying apparatus when a printing picture is divided with the ink supplying unit width, and
said noticed pixel setter being capable of selecting a region which has a high autocorrelation for each of the ink colors in a sensor pixel unit of an IRGB densitometer, and setting the remaining region of the selected region from which the edge portion corresponding to the predetermined sensor pixels are removed as the noticed pixel of the pertaining ink color for each of the ink colors in case that the noticed pixel remains in the selected region even if an edge portion with regard to the pertaining ink color corresponding to predetermined sensor pixels is removed from the selected region;
target color mixture halftone density setter to set a target color mixture halftone density regarding the noticed pixel for each of the ink colors for each of the ink supplying unit widths;
color mixture halftone density measurer to operate said IRGB densitometer to measure an actual color mixture halftone density for each of the ink supplying unit widths of the actually printed sheet;
target halftone dot area ratio arithmetic obtainer to obtain arithmetically e a target halftone dot area ratio of each ink color corresponding to the target color mixture halftone density based on a corresponding relationship set in advance between halftone dot area ratios and color mixture halftone densities;
actual halftone dot area ratio arithmetic obtainer to obtain arithmetically an actual halftone dot area ratio of each ink color corresponding to the actual color mixture halftone density based on the corresponding relationship between the halftone dot area ratios and the color mixture halftone densities;
target monochromatic halftone density arithmetic obtainer to determine a target monochromatic halftone density corresponding to the target halftone dot area ratio according to a corresponding relationship set in advance between the halftone dot area ratios and monochromatic halftone densities;
actual monochromatic halftone density arithmetic obtainer to determine an actual monochromatic halftone density corresponding to the actual halftone dot area ratio according to the corresponding relationship of said halftone dot area ratios and said monochromatic halftone densities;
solid density difference arithmetic obtainer to determine a solid density deviation corresponding to a deviation between the target monochromatic halftone density and the actual monochromatic halftone density under the target halftone dot area ratio according to a corresponding relationship set in advance among the halftone dot area ratios, the monochromatic halftone densities and solid densities; and
ink supplying amount adjuster to adjust an ink supplying amount for each of the ink supplying unit widths based on the solid density deviation.

14. The picture color tone controlling apparatus for a printing press as claimed in claim 13, wherein said noticed pixel setter sets, if the noticed pixel does not remain when the edge portion with regard to the ink color corresponding to the predetermined sensor pixels is removed from the selected region, the region which has the high autocorrelation as the noticed pixel of the pertaining ink color without removing the edge portion from the selected region.

15. The picture color tone controlling apparatus for a printing press as claimed in claim 13, wherein said noticed pixel setter removes, when the edge portion with regard to the pertaining ink color is removed in a unit of a sensor pixel from within the selected region, the edge portion by only one pixel in the sensor pixel unit.

16. The picture color tone controlling apparatus for a printing press as claimed in claim 13, wherein the region which has a high autocorrelation at said noticed pixel setter is a group of all those pixels which have an autocorrelation higher than a condition set in advance for each of the ink colors, and said noticed pixel setter is configured as noticed pixel automatic setter which automatically extracts the group of pixels.

17. The picture color tone controlling apparatus for a printing press as claimed in claim 16, further comprising noticed pixel manual setter to be operable by an operator to manually set the noticed pixel separately from said noticed pixel automatic setter, and said target color mixture halftone density setter, said actual color mixture halftone density measurer, said target halftone dot area ratio calculator, said actual halftone dot area ratio calculator, said target monochromatic halftone density calculator, said actual monochromatic halftone density calculator and said solid density deviation calculator carry out the respective processes for both of a first noticed pixel which is the noticed pixel set by said noticed pixel automatic setter and a second noticed pixel which is the noticed pixel set by said noticed pixel manual setter to obtain two solid density deviations, and said ink supplying amount adjuster adjusts the ink supplying amount for each of the ink supplying unit widths based on the two solid density deviations.

18. The picture color tone controlling apparatus for a printing press as claimed in claim 17, further comprising weighting setter to set a weighting condition for the solid density deviation obtained with regard to the first noticed pixel and the solid density deviation obtained with regard to the second noticed pixel, and said ink supplying amount adjuster weighted averages the solid density deviation obtained with regard to the first noticed pixel and the solid density deviation obtained with regard to the second noticed pixel in accordance with the weighting condition set by said weighting setter and adjusts the ink supplying amount for each of the ink supplying unit widths based on the solid density deviation obtained by the weighted averaging.

19. The picture color tone controlling apparatus for a printing press as claimed in claim 13, further comprising a conversion table which defines a corresponding relationship among the halftone dot area ratios, the color mixture halftone densities and color coordinate values in said IRGB densitometer, said target halftone dot area ratio arithmetic obtainer and said actual halftone dot area ratio arithmetic obtainer using said conversion table to determine the target halftone dot area ratio or the actual halftone dot area ratio.

20. The picture color tone controlling apparatus for a printing press as claimed in claim 19, wherein said target color mixture halftone density setter includes:
receiver to receive kcmy halftone dot area ratio data of a printing object picture from the outside;
noticed pixel setter to set a noticed pixel corresponding to each of the ink colors for each of the ink supplying unit widths from among the pixels which form the printing object picture; and
converter to convert the halftone dot area ratio of the noticed pixel into the color mixture halftone density using said conversion table;
said target color mixture halftone density setter setting the color mixture halftone density of the noticed pixel as the target color mixture halftone density;
said color mixture measurer measuring the actual color mixture halftone density of the noticed pixel.

21. The picture color tone controlling apparatus for a printing press as claimed in claim 19, wherein said target color mixture halftone density setter includes:
receiver to receive kcmy halftone dot area ratio data of a printing object picture and an ICC profile from the outside;
noticed pixel setter to set a noticed pixel corresponding to each of the ink colors for each of the ink supplying unit widths from among the pixels which form the printing object picture; and
converter to convert the halftone dot area ratio of the noticed pixel into the color mixture halftone density using the ICC profile and said conversion table;
said target color mixture halftone density setter setting the color mixture halftone density of the noticed pixel as the target color mixture halftone density;
said color mixture measurer measuring the actual color mixture halftone density of the noticed pixel.

22. The picture color tone controlling apparatus for a printing press as claimed in claim 19, further comprising:
actual color coordinate value arithmetic obtainer to determine an actual color coordinate value corresponding to the actual color mixture halftone density using said conversion table;
target color coordinate value arithmetic obtainer to determine a target color coordinate value corresponding to the target color mixture halftone density using said conversion table;
color difference arithmetic obtainer to determine a color difference between the actual color coordinate value and the target color coordinate value; and
display to display the actual color coordinate value and/or the color difference on a display apparatus.
